(19) United States
(12) Patent Application Publication
(10) Pub. No.: US 2025/0391819 A1
(43) Pub. Date: Dec. 25, 2025

(54) SEMICONDUCTOR DEVICE

(71) Applicant: Kioxia Corporation, Tokyo (JP)

(72) Inventor: Yasuo OTSUKA, Kawasaki Kanagawa (JP)

(73) Assignee: Kioxia Corporation, Tokyo (JP)

(21) Appl. No.: 19/064,801

(22) Filed: Feb. 27, 2025

(30) Foreign Application Priority Data
Jun. 19, 2024 (JP) 2024-098557

(51) Int. Cl. H01L 25/16; H01L 23/00; H10B 80/00; H10D 80/30

(52) U.S. Cl. CPC H01L 25/16; H01L 24/06; H01L 24/48; H10B 80/00; H10D 80/30; H01L 24/32; H01L 24/49; H01L 24/73; H01L 2224/06135; H01L 2224/32145; H01L 2224/32225; H01L 2224/48091; H01L 2224/48147; H01L 2224/48227; H01L 2224/49175; H01L 2224/73215; H01L 2224/73265; H01L 2225/06506; H01L 2225/0651; H01L 2225/06562; H01L 2924/1431

(57) ABSTRACT

According to one embodiment, a semiconductor device includes: a wiring substrate; a first laminated body that includes N first plate-shaped portions being laminated in the up-down direction above the wiring substrate; and a second laminated body that includes a second plate-shaped portion provided above the first laminated body and M third plate-shaped portions provided above the second plate-shaped portion, the second plate-shaped portion and the M third plate-shaped portions being laminated in the up-down direction, a second side of the first laminated body and the second laminated body opposite to a first side in a width direction has a stepped shape, and an end portion of the second laminated body on the second side is located closer to the second side than an end portion of the first laminated body on the second side.

### CROSS-REFERENCE TO RELATED APPLICATION

This application is based upon and claims the benefit of priority from Japanese Patent Application No. 2024-98557, filed on Jun. 19, 2024, the entire contents of which are incorporated herein by reference.

### BACKGROUND OF THE INVENTION

### Field of the Invention

The present embodiment relates to a semiconductor device.

### Description of the Related Art

Some semiconductor devices have multiple laminated chips disposed on substrates.

### BRIEF DESCRIPTION OF THE DRAWINGS

FIG. 1 is a schematic diagram illustrating a section parallel to a YZ plane of a semiconductor device according to a first embodiment;

FIG. 2 is a plan view of a semiconductor chip according to the first embodiment seen from above;

FIG. 3 is a plan view of a plate-shaped portion 411 seen from above;

FIG. 4 is a plan view of a plate-shaped portion 412 seen from above;

FIG. 5 is a schematic diagram illustrating a manufacturing process of the semiconductor device according to the first embodiment and illustrating the section parallel to the YZ plane;

FIG. 6 is a schematic diagram illustrating the manufacturing process of the semiconductor device according to the first embodiment and illustrating the section parallel to the YZ plane;

FIG. 7 is a schematic diagram illustrating the manufacturing process of the semiconductor device according to the first embodiment and illustrating the section parallel to the YZ plane;

FIG. 8 is a schematic diagram illustrating the manufacturing process of the semiconductor device according to the first embodiment and illustrating the section parallel to the YZ plane;

FIG. 9 is a schematic diagram illustrating the manufacturing process of the semiconductor device according to the first embodiment and illustrating the section parallel to the YZ plane;

FIG. 10 is a schematic diagram illustrating the manufacturing process of the semiconductor device according to the first embodiment and illustrating the section parallel to the YZ plane;

FIG. 11 is a schematic diagram illustrating the manufacturing process of the semiconductor device according to the first embodiment and illustrating the section parallel to the YZ plane;

FIG. 12 is a schematic diagram illustrating the manufacturing process of the semiconductor device according to the first embodiment and illustrating the section parallel to the YZ plane;

FIG. 13 is a schematic diagram illustrating the manufacturing process of the semiconductor device according to the first embodiment and illustrating the section parallel to the YZ plane;

FIG. 14 is a schematic diagram illustrating a section of a semiconductor device according to a comparative example in a side view;

FIG. 15 is a plan view of a semiconductor chip according to the comparative example seen from above;

FIG. 16 is a schematic diagram illustrating a section of a semiconductor device according to a second embodiment;

FIG. 17 is a schematic diagram illustrating a manufacturing process of the semiconductor device according to the second embodiment and illustrating a section parallel to a YZ plane;

FIG. 18 is a schematic diagram illustrating the manufacturing process of the semiconductor device according to the second embodiment and illustrating the section parallel to the YZ plane;

FIG. 19 is a schematic diagram illustrating a section of a semiconductor device according to a first modification of the second embodiment;

FIG. 20 is a schematic diagram illustrating a section of a semiconductor device according to a second modification of the second embodiment;

FIG. 21 is a schematic diagram illustrating a section of a semiconductor device according to a third modification of the second embodiment;

FIG. 22 is a schematic diagram illustrating a section of a semiconductor device according to a fourth modification of the second embodiment;

FIG. 23 is a schematic diagram illustrating a section of a semiconductor device according to a fifth modification of the second embodiment;

FIG. 24 is a schematic diagram illustrating a section of a semiconductor device according to a sixth modification of the second embodiment;

FIG. 25 is a schematic diagram illustrating a section of a semiconductor device according to a seventh modification of the second embodiment;

FIG. 26 is a schematic diagram illustrating a section of a semiconductor device according to a third embodiment;

FIG. 27 is a schematic diagram illustrating a section of a semiconductor device according to a fourth embodiment;

FIG. 28 is a schematic diagram illustrating a manufacturing process of the semiconductor device according to the fourth embodiment and illustrating a section parallel to a YZ plane;

FIG. 29 is a schematic diagram illustrating the manufacturing process of the semiconductor device according to the fourth embodiment and illustrating the section parallel to the YZ plane; and

FIG. 30 is a schematic diagram illustrating the manufacturing process of the semiconductor device according to the fourth embodiment and illustrating the section parallel to the YZ plane.

### DETAILED DESCRIPTION OF THE INVENTION

Hereinafter, present embodiments will be described with reference to the accompanying drawings. For easiness of understanding of description, the same components in each drawing will be denoted by the same reference signs as much as possible, and repeated description will be omitted.

### First Embodiment

Hereinafter, a configuration of a semiconductor device according to a first embodiment will be described. An X axis, a Y axis, and a Z axis may be illustrated in each drawing. The X axis, the Y axis, and the Z axis form a right-handed three-dimensional orthogonal coordinate system. Hereinafter, an arrow direction of the X axis may be referred to as an X-axis+direction, a direction opposite to the arrow may be referred to as an X-axis−direction, and the same applies to the other axes. Note that the Z-axis+direction and the Z-axis−direction may be referred to as an “upper side” and a “lower side”, respectively. Also, planes that perpendicularly intersect the X axis, the Y axis, and the Z axis may be referred to as a YZ plane, a ZX plane, and an XY plane, respectively. The Z-axis direction may be referred to as an “up-down direction”. The terms “upper side,” “lower side,” and “up-down direction” are terms that just indicate relative positional relationships within the drawings and are not terms that define orientations with reference to a vertical direction.

The dimensions of the components illustrated in each drawing may be represented differently from the actual dimensions unless particularly specifically described otherwise for easiness of understanding of the description.

In the present specification, “connection” includes not only physical connections but also electrical connections, and unless specifically stated otherwise, it includes not only direct connections but also indirect connections.

In the present specification, “formed above something” refers not only to cases where it is formed in contact with something on the upper side and also cases where it is formed above with an intervention of something else unless specifically stated otherwise. The same applies to “formed below something” and the like.

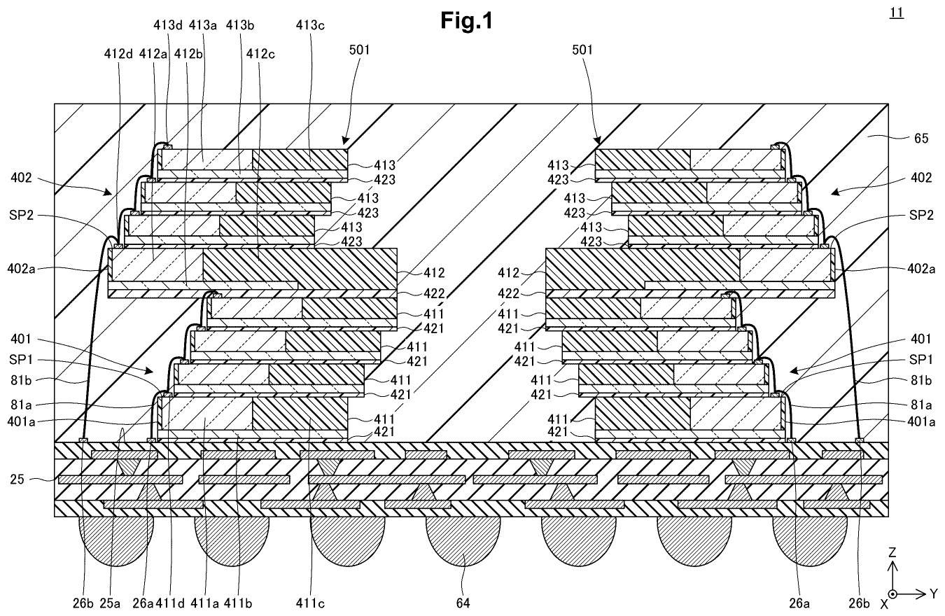

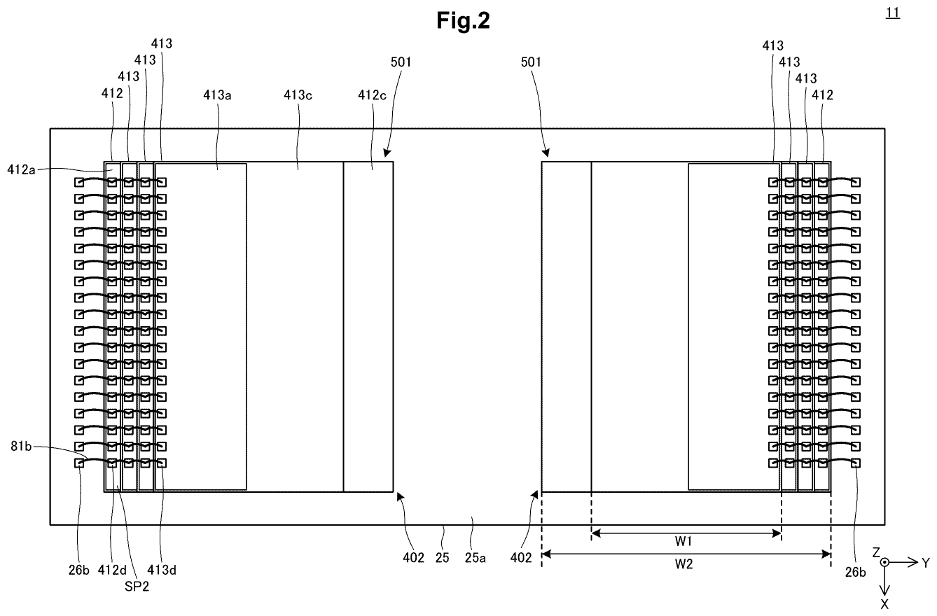

FIG. 1 is a schematic diagram illustrating a section parallel to a YZ plane of the semiconductor device according to the first embodiment. FIG. 2 is a plan view of a semiconductor chip according to the first embodiment seen from above. Note that for clarity of the description, sealing resin 65 is not illustrated in FIG. 2.

As illustrated in FIGS. 1 and 2, a semiconductor device 11 includes a wiring substrate 25, the sealing resin 65 (an example of a “sixth resin layer”), and two one-tower structures 501. Each one-tower structure 501 includes bonding wires 81a (an example of a “first bonding wire”) and 81b (an example of a “second bonding wire”) and laminated bodies 401 (an example of a “first laminated body”) and 402 (an example of a “second laminated body”).

One of the two one-tower structures 501 is obtained by causing the other one-tower structure 501 to rotate by 180° with the Z axis as a rotation axis. Although the one-tower structure 501 on the side of the Y-axis−direction will be described as a representative, the same applies to the one-tower structure 501 on the side of the Y-axis+direction.

The wiring substrate 25 has a surface 25a (an example of a “main surface”) that intersects the up-down direction (Z-axis direction). In the present embodiment, the surface 25a is substantially parallel to the XY plane.

A plurality substrate electrodes 26a and a plurality of substrate electrodes 26b are provided on the surface 25a.

A bonding finger is formed by the plurality of substrate electrodes 26a being aligned in a line in the X-axis direction. The bonding finger of the substrate electrodes 26a is located on the side of the Y-axis−direction of the one-tower structure 501.

Similarly, a bonding finger is formed by the plurality of substrate electrodes 26b being aligned in a line in the X direction. The bonding finger of the substrate electrodes 26b is located on the side of the Y-axis−direction of the bonding finger of substrate electrodes 26a.

A surface of the wiring substrate 25 on the lower side is provided with a plurality of solder balls 64. An electrode pattern (not illustrated) is formed in the wiring substrate 25. Some or all of the substrate electrodes 26a and 26b are electrically connected to the plurality of solder balls 64 via the electrode pattern formed in the wiring substrate 25.

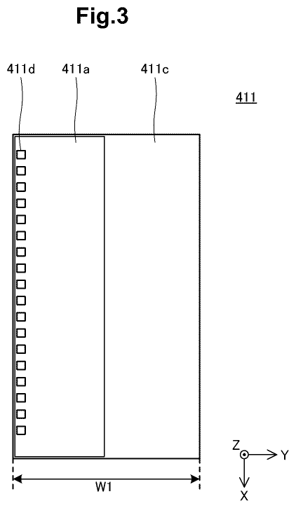

FIG. 3 is a plan view of a plate-shaped portion 411 seen from above. As illustrated in FIGS. 1 to 3, the laminated body 401 includes N (where N is an integer of equal to or greater than two) plate-shaped portions 411 (an example of “first plate-shaped portions”) and N die attachment films 421. In the present embodiment, the laminated body 401 includes four plate-shaped portions 411 and four die attachment films 421.

Each plate-shaped portion 411 has a width W1 (an example of a “first width”) in the Y-axis direction (an example of a “first width direction”) that intersects the up-down direction. Note that the width W1 of each plate-shaped portion 411 may vary within a range of manufacturing tolerances.

In the present embodiment, the thickness of the lowermost plate-shaped portion 411 among the four plate-shaped portions 411 is thicker than the thicknesses of the other three plate-shaped portions 411. Note that the thickness of each plate-shaped portion 411 in the up-down direction may be the same.

Each plate-shaped portion 411 includes a memory chip 411a (an example of a “first memory chip”), a complementary metal-oxide-semiconductor (CMOS) chip 411b (an example of a “second semiconductor chip”), mold resin 411c (an example of a “resin layer”), and a plurality of electrode pads 411d (an example of “first electrode pads”).

The memory chip 411a is, for example, a NAND-type flash memory chip. The memory chip 411a is located closer to an end portion of the plate-shaped portion 411 on the side of the Y-axis−direction than to an end portion of the plate-shaped portion 411 on the side of the Y-axis+direction.

An upper surface of memory chip 411a is provided with the plurality of electrode pads 411d. The number of electrode pads 411d is the same as the number of the substrate electrodes 26a that form the bonding finger.

The plurality of electrode pads 411d are located closer to the end of the memory chip 411 on the side of the Y-axis−direction than to the end thereof on the side of the Y-axis+direction and are aligned in a line in the X-axis direction. The plurality of electrode pads 411d are electrically connected to the plurality of substrate electrodes 26a, respectively, through the bonding wires 81a.

The CMOS chip 411b controls the memory chip 411a. The memory chip 411a is affixed to a part of an upper surface of the CMOS chip 411b (hereinafter, referred to as an affixed surface in some cases). The CMOS chip 411b and the memory chip 411a are electrically and mechanically coupled through direct bonding. Details of the direct bonding will be described later.

The mold resin 411c is connected to the memory chip 411a on the side of the Y-axis+direction (an example of a “first side”).

In the present embodiment, the mold resin 411c is connected to the upper surface of the CMOS chip 411b except for the affixed surface and a side surface of the memory chip 411a parallel to the ZX plane and a side surface thereof parallel to the YZ plane. The width of the mold resin 411c in the Y-axis direction and the width of the CMOS chip 411b are W1. The width W1 of the CMOS chip 411b is wider than the width of the memory chip 411a in the Y-axis direction.

The lower surface of the CMOS chip 411b is provided with the die attachment films 421.

Details of a method of manufacturing the plate-shaped portions 411 will be described later.

The four plate-shaped portions 411 are laminated in the up-down direction above the wiring substrate 25. Specifically, the lowermost plate-shaped portion 411 is connected to the surface 25a of the wiring substrate 25 by a die attachment film 421 having a width W1 in the Y-axis direction, for example. The second plate-shaped portion 411 from the bottom is connected to the upper surface of the lowermost plate-shaped portion 411 by a die attachment film 421. In this manner, the four plate-shaped portions 411 are laminated to form the laminated body 401.

The side of the Y-axis−direction (an example of a “second side”) of the laminated body 401 opposite to the side of the Y-axis+direction has a stepped shape. The steps have step surfaces (terrace surfaces) SP1 parallel to the XY plane. The electrode pads 411d are located on the step surfaces SP1.

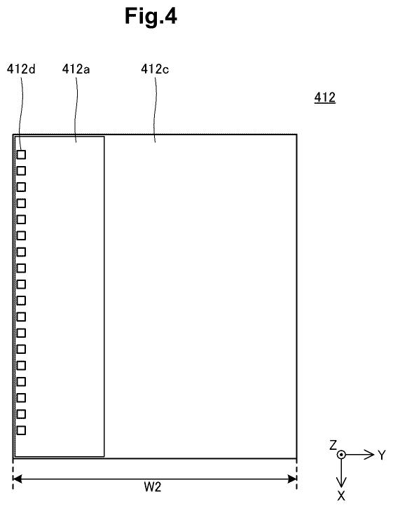

FIG. 4 is a plan view of the plate-shaped portion 412 seen from above. As illustrated in FIGS. 1 to 4, the laminated body 402 includes a plate-shaped portion 412 (an example of a “second plate-shaped portion”), M (where M is an integer of equal to or greater than one) plate-shaped portions 413 (an example of “third plate-shaped portions”), a die attachment film 422, and M die attachment films 423.

In the present embodiment, the laminated body 402 includes a plate-shaped portion 412, three plate-shaped portions 413, a die attachment film 422, and three die attachment films 423.

The plate-shaped portion 412 is provided above the laminated body 401 and has a width W2 (an example of a “second width”) that is wider than the width W1 in the Y-axis direction. The plate-shaped portion 412 includes a memory chip 412a (an example of a “second memory chip”), a CMOS chip 412b (an example of the “second semiconductor chip”), mold resin 412c (an example of a “first resin layer”), and a plurality of electrode pads 412d (an example of “second electrode pads”).

Memory chip 412a is, for example, a NAND-type flash memory chip similar to the memory chip 411a. The memory chip 412a is located closer to an end portion of the plate-shaped portion 412 on the side of the Y-axis−direction than to an end portion of the plate-shaped portion 412 on the side of the Y-axis+direction. The width of the memory chip 412a in the Y-axis direction is substantially the same as the width of the memory chip 411a in the Y-axis direction.

An upper surface of the memory chip 412a is provided with the plurality of electrode pads 412d. The number of electrode pads 412d is the same as the number of the substrate electrodes 26b that form the bonding finger.

The plurality of electrode pads 412d are located closer to an end of the memory chip 412a on the side of the Y-axis−direction than to an end thereof on the side of the Y-axis+direction and are aligned in a line in the X-axis direction. The plurality of electrode pads 412d are electrically connected to the plurality of substrate electrodes 26b, respectively, through a bonding wire 81b.

The CMOS chip 412b is, for example, a chip similar to the CMOS chip 411b. The CMOS chip 412b controls the memory chip 412a. The width of the CMOS chip 412b in the Y-axis direction is substantially the same as the width of the CMOS chip 411b in the Y-axis direction. The memory chip 412a is affixed to part (hereinafter, referred to as an affixed surface in some cases) of an upper surface of the CMOS chip 412b.

The mold resin 412c is connected to the memory chip 412a on the side of the Y-axis+direction (an example of the “first side”).

In the present embodiment, the mold resin 412c is connected to the upper surface of the CMOS chip 412b except for the affixed surface and a side surface of the memory chip 412a parallel to the ZX plane and a side surface thereof parallel to the YZ plane.

The width of the mold resin 412c in the Y-axis direction is wider than the width of the CMOS chip 412b in the Y-axis direction. Specifically, the mold resin 412c extends on the side of the Y-axis+direction as compared with the end portion of the CMOS chip 412b on the side of the Y-axis+direction.

Therefore, the width W2 of the plate-shaped portion 412 is wider than the width W1 of the plate-shaped portions 411. In other words, the plate-shaped portion 412 is extended on the side of the Y-axis+direction by the mold resin 412c as compared with the plate-shaped portions 411. Hereinafter, the mold resin 412c on the side of the Y-axis+direction as compared with the end portion of the CMOS chip 412b on the side of the Y-axis+direction may be referred to as an extended portion.

A lower surface of the CMOS chip 412b and a lower surface of the extended portion of the mold resin 412c are provided with the die attachment film 422 having a width that is wider than the width W1 of the die attachment films 421 in the Y-axis direction, for example, a width W2. Details of a method of manufacturing the plate-shaped portion 412 will be described later.

As illustrated in FIGS. 1 to 3, the three plate-shaped portions 413 are provided above the plate-shaped portion 412. The plate-shaped portions 413 have the width W1 in the Y-axis direction. Note that the width W1 of each plate-shaped portion 413 may vary within a range of manufacturing tolerances.

Each plate-shaped portion 413 includes a memory chip 413a (an example of a “third memory chip”), a CMOS chip 413b (an example of the “second semiconductor chip”), mold resin 413c (an example of the “resin layer”), and a plurality of electrode pads 413d (an example of “third electrode pads”).

The memory chip 413a, the CMOS chip 413b, the mold resin 413c, the electrode pads 413d, and the die attachment films 423 are similar to the memory chip 411a, the CMOS chip 411b, the mold resin 411c, the electrode pads 411d, and the die attachment films 421 in the plate-shaped portions 411, respectively.

The memory chip 413a is located closer to an end portion of the plate-shaped portion 413 on the side of the Y-axis−direction than to an end portion of the plate-shaped portion 413 on the side of the Y-axis+direction. An upper surface of the memory chip 413a is provided with the same number of electrode pads 413d as the number of substrate electrodes 26b that form the bonding finger.

The plurality of electrode pads 413d are located closer to the end of the memory chip 413a on the side of the Y-axis−direction than to the end thereof on the side of the Y-axis+direction and are aligned in a line in the X-axis direction. The plurality of electrode pads 413d are electrically connected to the plurality of substrate electrodes 26b, respectively, through the bonding wire 81b.

The plate-shaped portion 412 and the three plate-shaped portions 413 are laminated in the up-down direction above the laminated body 401. Specifically, the lowermost plate-shaped portion 412 is connected to the upper surface of the uppermost plate-shaped portion 411 in the laminated body 401 by the die attachment film 422. The thickness of the die attachment film 422 in the up-down direction is thicker than the die attachment films 421 and 423 to bury the bonding wire 81a.

The second plate-shaped portion 413 from the bottom is connected to the upper surface of the lowermost plate-shaped portion 412 by a die attachment film 423. In this manner, the plate-shaped portion 412 and the three plate-shaped portions 411 are laminated to form the laminated body 402.

The side of the Y-axis−direction of the laminated body 402 has a stepped shape. The steps have step surfaces (terrace surfaces) SP2 parallel to the XY plane. The electrode pads 412d or 413d are located on the step surfaces SP2.

In a plan view of the surface 25a of the wiring substrate 25, an end portion 402a of the laminated body 402 on the side of the Y-axis−direction is located on the side of the Y-axis−direction as compared with an end portion 401a of the laminated body 401 on the side of the Y-axis−direction.

The sealing resin 65 seals at least the one-tower structures 501. Specifically, the sealing resin 65 buries the two one-tower structures 501 and the surface 25a of the wiring substrate 25 above the wiring substrate 25. The two one-tower structures 501 and the surface 25a of the wiring substrate 25 are insulation-sealed by the sealing resin 65.

The sealing resin 65 has a composition different from the composition of the mold resin 411c, 412c, or 413c. In addition, the sealing resin 65 has a composition different from the composition of the die attachment films 421, 422, or 423.

Specifically, materials of the sealing resin 65, materials of the mold resin 411c, 412c, or 413c, and materials of the die attachment films 421, 422, or 423 are different from each other.

Note that some or all of these materials may be the same.

More specifically, the mold resin 411c, 412c, or 413c is resin used, for example, in a fluororesin substrate without a glass cloth. Note that the mold resin 411c, 412c, or 413c may contain a glass cloth. This allows for an increase in hardness of the mold resin 411c, 412c, or 413c.

### [Method of Manufacturing Semiconductor Device 11]

Hereinafter, a method of manufacturing the semiconductor device 11 will be described as an example of a method of manufacturing a semiconductor device according to the present embodiment.

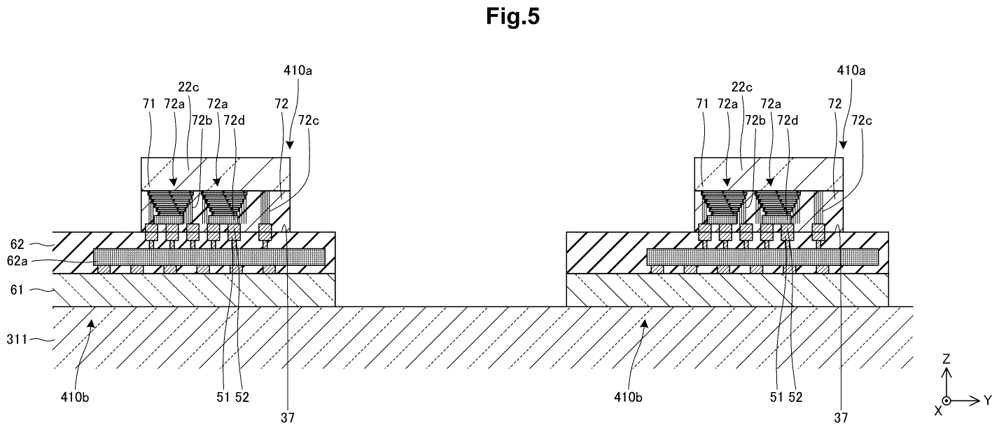

First, CMOS chips 410b are placed above a silicon wafer 311 as illustrated in FIG. 5. CMOS circuits are formed on upper surfaces of semiconductor layers 61 in the CMOS chips 410b. Also, insulating layers 62 including pads 51 (an example of “first pads”) and wiring layers 62a are formed above the CMOS circuits in the semiconductor layers 61. The pads 51 are formed to be exposed in substantially the same plane as affixed surfaces 37 above the insulating layers 62.

In addition, insulating layers 72 including memory arrays 72a, vias 72b and 72c, wiring layers 72d, pads 52 (an example of “second pads”) and the like are formed below the semiconductor layers 71 in memory chips 410a. The semiconductor layers 71 contain, for example, silicon. The pads 52 are formed to be exposed in substantially the same plane as the lower surfaces of the insulating layers 72. The vias 72c have a shape extending in the up-down direction. Lower end portions of the vias 72c are electrically connected to the pads 52.

The memory chips 410a and the CMOS chips 410b are affixed at the affixed surfaces 37 by performing annealing in a state where the pads 51 and the pads 52 are in contact with each other and joining the pads 51 and the pads 52. Specifically, the pads 51 and the pads 52 are joined through direct bonding in which copper contained in the pads 51 and copper contained in the pads 52 are directly coupled to each other. In this manner, the pads 51 and the pads 52 are electrically and mechanically coupled to each other. At this time, the upper surfaces of the insulating layers 62 and the lower surfaces of the insulating layers 72 are coupled by hydrogen bonding.

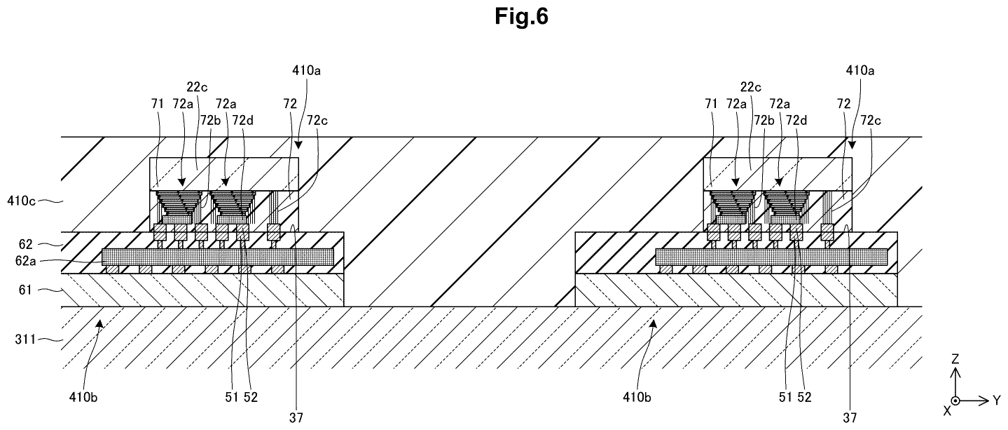

Next, mold resin 410c is formed above the silicon wafer 311 as illustrated in FIG. 6. In this manner, the memory chips 410a and the CMOS chips 410b are sealed with the mold resin 410c.

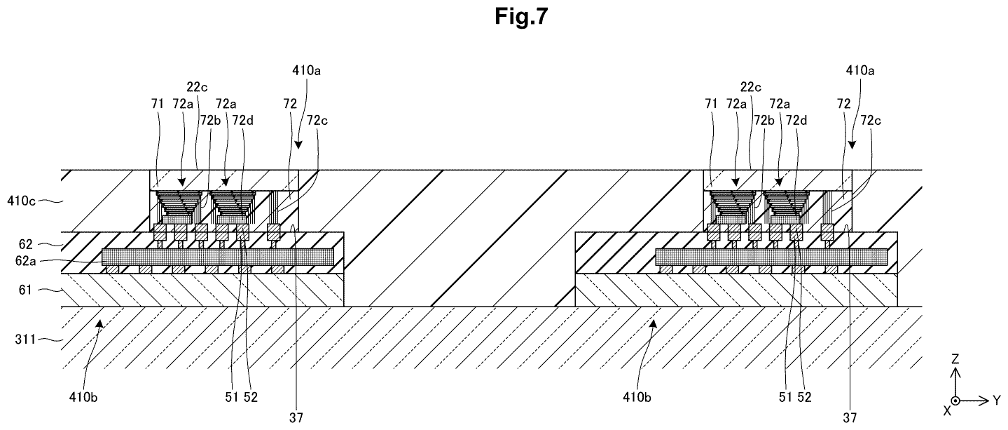

Next, the upper surfaces of the semiconductor layers 71, that is, surfaces 22a of the memory chips 410a are exposed from the mold resin 410c by the upper surfaces of the mold resin 410c being subjected to chemical mechanical polishing as illustrated in FIG. 7. Then, the silicon wafer 311 is subjected to degas annealing.

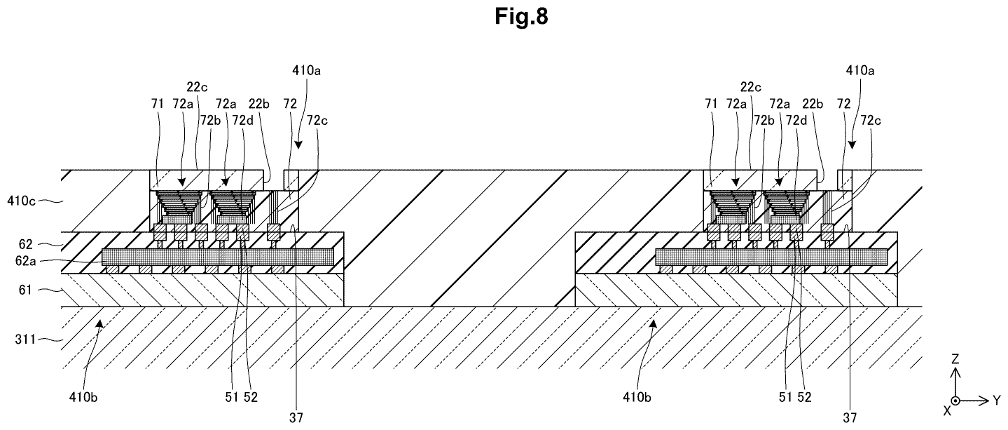

Next, film formation, resist application, exposure, development, peeling, and the like are performed on the surfaces 22c of the memory chips 410a by a photo engraving process (PEP) method, and hole portions 22b penetrating through the memory chips 410a up to the insulating layers 72 are then formed by reactive ion etching in the memory chips 410a, as illustrated in FIG. 8.

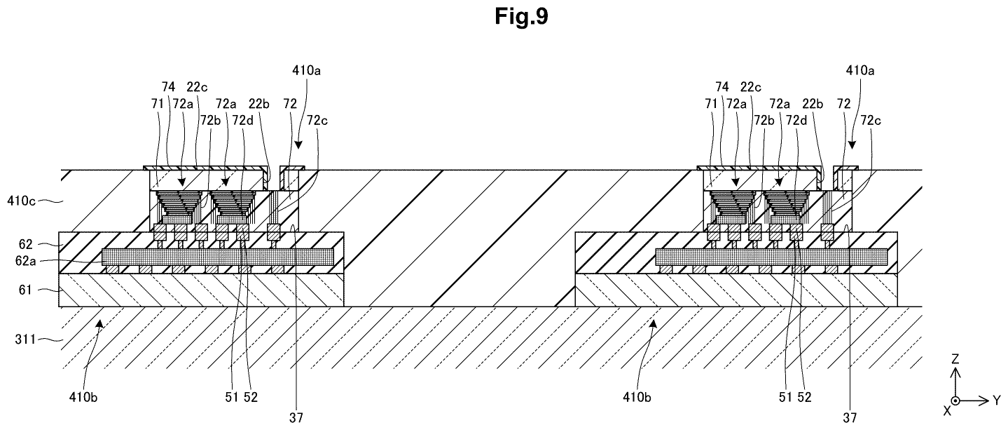

Next, film formation, resist application, exposure, development, peeling, and the like are performed on the surfaces 22c of the memory chips 410a by the PEP method, and insulating layers 74 containing polyimide, for example, are then formed above the memory chips 410a, as illustrated in FIG. 9.

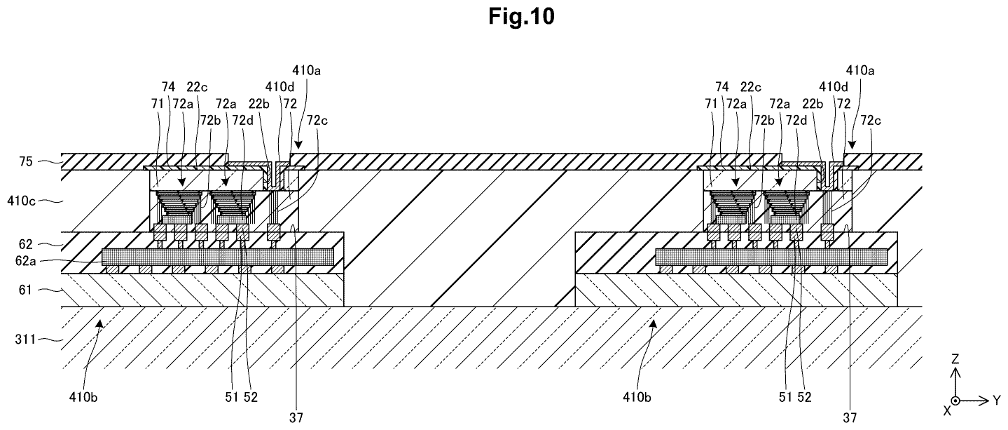

Next, an insulating layer 75 which is a resist is formed by performing film formation, resist application, exposure, development, peeling, and the like on upper surfaces of the insulating layers 74 by the PEP method as illustrated in FIG. 10. Then, electrode pads 410d are formed by depositing nickel and gold.

The electrode pads 410d are electrically connected to upper end portions of the vias 72c. In this manner, the electrode pads 410d are electrically connected to the CMOS circuits formed in the semiconductor layers 61 through the vias 72c, the pads 52, the pads 51, and the wiring layers 62a.

The CMOS circuits are electrically connected to the memory arrays 72a through the wiring layers 62a, the pads 51, the pads 52, and the wiring layers 72d or the vias 72b.

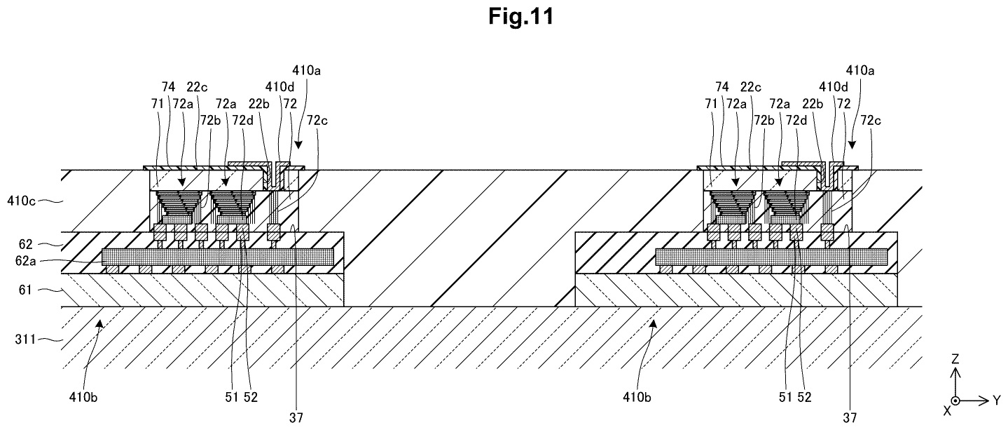

Next, the insulating layer 75 is removed by etching, for example, as illustrated in FIG. 11.

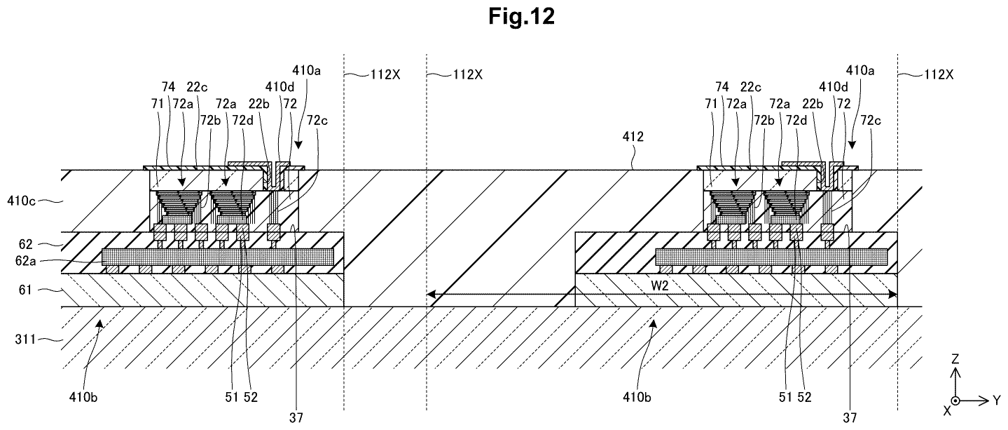

Next, the silicon wafer 311 is diced along dicing lines 112X, and a part of the silicon wafer 311 is separated into the plate-shaped portion 412 by performing chemical mechanical polishing on the lower surface of the separated silicon wafer 311 as illustrated in FIG. 12 (see FIGS. 1 and 4). Silicon wafer 311 is removed, for example, by the chemical mechanical polishing. Note that a part of the silicon wafer 311 may be left by the chemical mechanical polishing.

The separated memory chips 410a, the CMOS chips 410b, the mold resin 410c, and the electrode pads 410d are memory chips 412a, CMOS chips 412b, mold resin 412c, and electrode pads 412d, respectively.

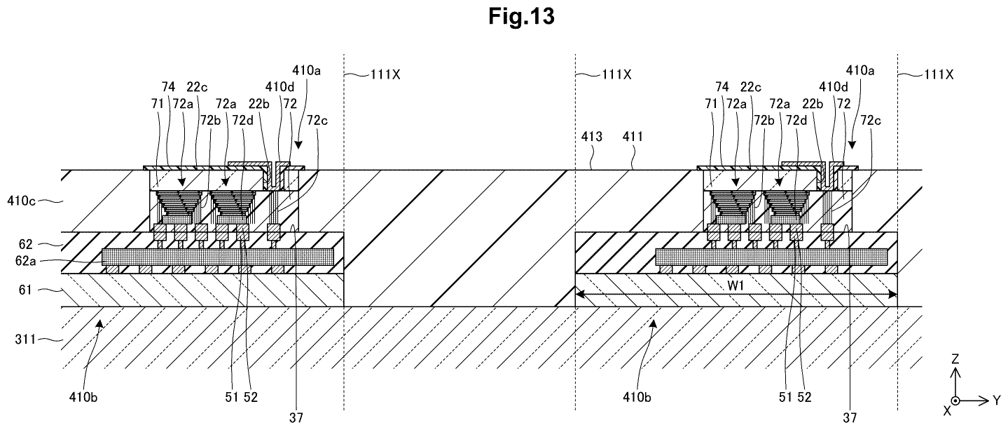

As illustrated in FIG. 13, the silicon wafer 311 is diced along dicing lines 111x, and a part of the silicon wafer 311 is separated into the plate-shaped portion 411 or 413 by performing chemical mechanical polishing on the lower surface of the separated silicon wafer 311 (see FIGS. 1 to 3). The separated memory chips 410a, the CMOS chips 410b, the mold resin 410c, and the electrode pads 410d are memory chips 411a, CMOS chips 411b, mold resin 411c, and electrode pads 411d, respectively. The plate-shaped portions 413 have a configuration similar to that of the plate-shaped portions 411, and description thereof will thus be omitted.

Next, the laminated body 401 is formed by the four plate-shaped portions 411 being disposed on the surface 25a of the wiring substrate 25 or the upper surfaces of the plate-shaped portions 411 located below via the die attachment films 421 as illustrated in FIG. 1. Then, the plate-shaped portion 412 is disposed on the upper surface of the laminated body 401 via the die attachment film 422, and the three plate-shaped portions 413 are disposed on the upper surface of the plate-shaped portion 412 or on the upper surfaces of the plate-shaped portions 413 located below via the die attachment films 423, thereby forming the laminated body 402.

### Effects

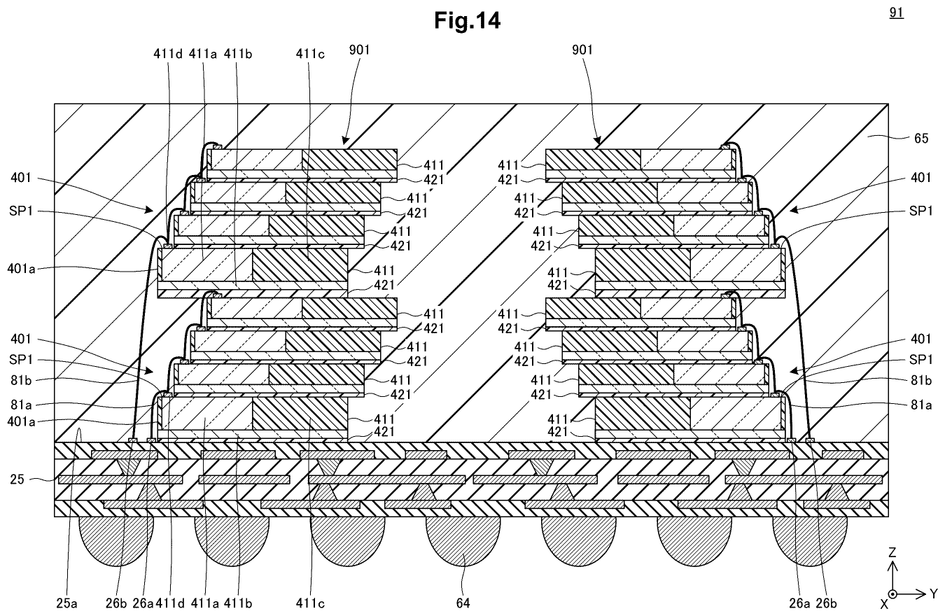

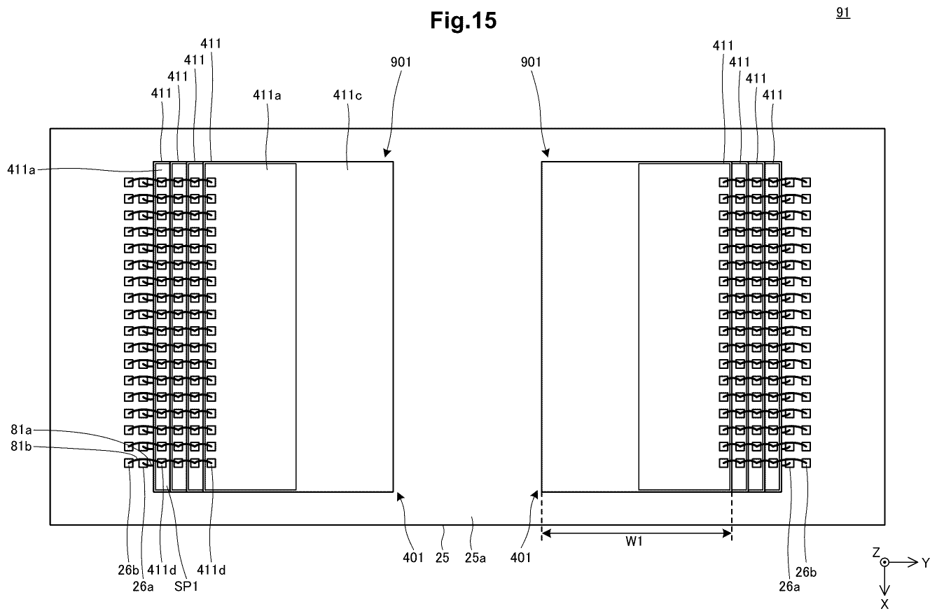

FIG. 14 is a schematic diagram illustrating a section of a semiconductor device according to a comparative example in a side view. FIG. 15 is a plan view of a semiconductor chip according to the comparative example seen from above. Note that for easiness of description, sealing resin 65 is not illustrated in FIG. 15.

As illustrated in FIGS. 14 and 15, a semiconductor device 91 according to the comparative example includes two one-tower structures 901 instead of the two one-tower structures 501 as compared with the semiconductor device 11 (see FIG. 1).

In each one-tower structure 901, a laminated body 401 is provided above a laminated body 401. In the one-tower structure 901, end portions 402a of two laminated bodies 401 on the side of the Y-axis−direction are aligned in a plan view of a surface 25a of a wiring substrate 25.

For this reason, a plurality of substrate electrodes 26a that form a bonding finger and a plurality of substrate electrodes 26b that form a bonding finger are disposed in close proximity, resulting in a high density of the substrate electrodes 26a and 26b. Moreover, if the substrate electrodes 26a and the substrate electrodes 26b are disposed to be spaced apart from each other, the length of the bonding wire 81b becomes longer.

On the contrary, according to the semiconductor device 11, it is possible to stably realize disposition in which the end portion 402a of the laminated body 402 is located on the side of the Y-axis−direction as compared with the end portion 401a of the laminated body 401 in a plan view of the surface 25a of the wiring substrate 25 with the configuration in which the width W2 of the plate-shaped portion 412 in the laminated body 402 is wider than the width W1 of the plate-shaped portions 411 in the laminated body 401.

In this manner, it is possible to dispose the substrate electrodes 26a and the substrate electrodes 26b to be spaced apart from each other without increasing the length of the bonding wire 81b and to thereby reduce the density of the substrate electrodes 26a and 26b. Also, it is possible to increase the distance between the bonding wires 81a and 81b and to thereby provide a semiconductor device capable of improving quality by reducing a mounting failure of the bonding wires 81a and 81b.

### Second Embodiment

A semiconductor device according to a second embodiment will be described. In the second embodiment and thereafter, descriptions of matters common to those in the first embodiment will be omitted, and only differences will be described. In particular, similar effects achieved by similar configurations will not be mentioned every time in each embodiment.

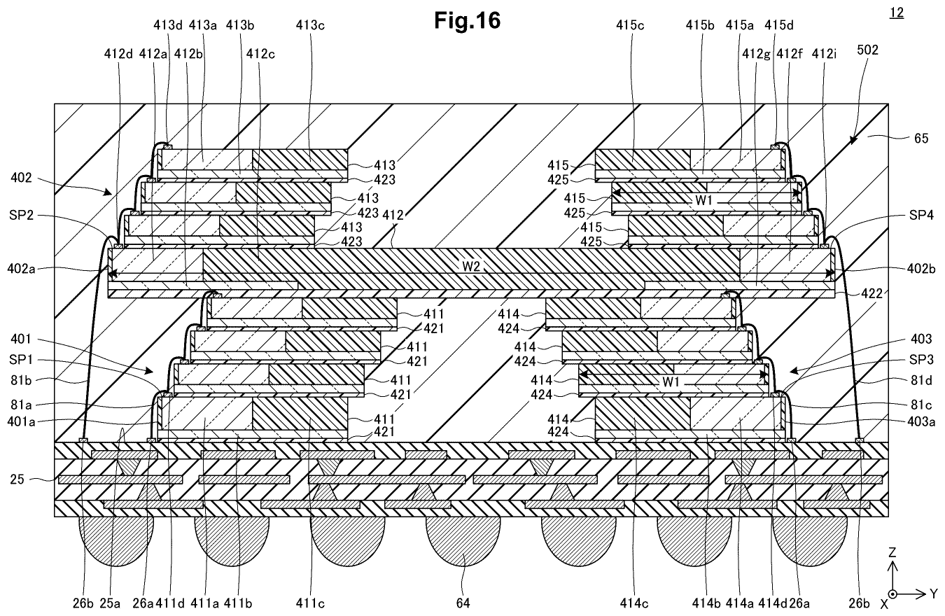

FIG. 16 is a schematic diagram illustrating a section of the semiconductor device according to the second embodiment. Note that how to interpret FIG. 16 is similar to that of FIG. 1.

As illustrated in FIG. 16, a semiconductor device 12 differs from the semiconductor device 11 according to the first embodiment in that a two-tower coupled structure 502 is formed by two plate-shaped portions 412 included in two one-tower structures 501 are combined and integrated as compared with the semiconductor device 11 illustrated in FIG. 1.

The semiconductor device 12 includes the two-tower coupled structure 502 instead of the two one-tower structures 501 as compared with the semiconductor device 11 illustrated in FIG. 1.

The two-tower coupled structure 502 includes bonding wires 81a (an example of the “first bonding wire”), 81b (an example of the “second bonding wire”), 81c (an example of a “third bonding wire”), and 81d (an example of a “fourth bonding wire”) and laminated bodies 401 (an example of the “first laminated body”), 402 (an example of the “second laminated body”), and 403 (an example of a “third laminated body”).

The laminated body 403 includes N plate-shaped portions 414 (an example of “fourth plate-shaped portions”) and N die attachment films 424. In the present embodiment, the laminated body 403 has the same configuration as the laminated body 401 rotated by 180° with the Z axis as a rotation axis.

Specifically, the laminated body 403 includes four plate-shaped portions 414 and four die attachment films 424. The plate-shaped portions 414 have a width W1 in the Y-axis direction. Note that the width W1 of each plate-shaped portion 414 may vary within a range of manufacturing tolerances.

Each plate-shaped portions 414 includes a memory chip 414a (an example of a “fourth memory chip”), a CMOS chip 414b (an example of the “second semiconductor chip”), mold resin 414c (an example of the “resin layer”), and a plurality of electrode pads 414d (an example of “fourth electrode pads”).

The memory chip 414a, the CMOS chip 414b, the mold resin 414c, the electrode pads 414d, and the die attachment films 424 are the same as the memory chip 411a, the CMOS chip 411b, the mold resin 411c, the electrode pads 411d, and the die attachment films 421 in each plate-shaped portion 411.

The memory chip 414a is located closer to an end portion of the plate-shaped portion 414 on the side of the Y-axis+direction than an end portion of the plate-shaped portion 414 on the side of the Y-axis−direction. An upper surface of the memory chip 414a is provided with the same number of electrode pads 414d as the number of substrate electrodes 26a that form a bonding finger.

The plurality of electrode pads 414d are located closer to an end of the memory chip 414a on the side of the Y-axis+direction than to an end of thereof on the side of the Y-axis−direction and are aligned in a line in the X-axis direction. The plurality of electrode pads 414d are electrically connected to the plurality of substrate electrodes 26a, respectively, through the bonding wire 81c.

The four plate-shaped portions 414 are laminated in the up-down direction on the side of the Y-axis+direction of the laminated body 401. Specifically, the lowermost plate-shaped portion 414 is connected to the surface 25a of the wiring substrate 25 by a die attachment film 424 having a width W1 in the Y-axis direction, for example. The second plate-shaped portion 414 from the bottom is connected to the upper surface of the lowermost plate-shaped portion 414 by a die attachment film 424. In this manner, the four plate-shaped portions 414 are laminated to form the laminated body 403.

The side of the Y-axis+direction of the laminated body 403 has a stepped shape. The steps have step surfaces (terrace surfaces) SP3 parallel to the XY plane. The electrode pads 414d are located on the step surface SP3.

The laminated body 402 in the semiconductor device 12 further includes three plate-shaped portions 415 (an example of “fifth plate-shaped portions”) and three die attachment films 425 as compared with the laminated body 402 illustrated in FIG. 1.

A plate-shaped portion 412 in the semiconductor device 12 further includes a memory chip 412f (an example of a “fifth memory chip”), a CMOS chip 412g, and a plurality of electrode pads 412i (an example of “fifth electrode pads”) as compared with the plate-shaped portion 412 illustrated in FIG. 1.

The plate-shaped portion 412 is provided over the upper surface of the laminated body 401 and the upper surface of the laminated body 403.

The die attachment film 422 (an example of a “second resin layer”) is provided between the plate-shaped portion 412 in the laminated body 402 and the laminate bodies 401 and 403. Specifically, the upper surface of the die attachment film 422 is in contact with the lower surface of the plate-shaped portion 412. The lower surface of the die attachment film 422 is in contact with the upper surface of the laminated body 401 and the upper surface of the laminated body 403.

The memory chip 412f in the plate-shaped portion 412 has the same configuration as that of the memory chip 412a rotated by 180° with the Z axis as a rotation axis.

The memory chip 412f is provided on the side of the Y-axis+direction of the mold resin 412c. In the present embodiment, the memory chip 412f is located closer to an end portion of the plate-shaped portion 412 on the side of the Y-axis+direction than to an end portion of the plate-shaped portion 412 on the side of the Y-axis−direction and is connected to the mold resin 412c on the side of the Y-axis+direction.

The upper surface of the memory chip 412f is provided with the same number of electrode pads 412i as the number of substrate electrodes 26b that form the bonding finger.

The plurality of electrode pads 412i are located closer to an end of the memory chip 412f on the side of the Y-axis+direction than to an end thereof on the side of the Y-axis−direction and are aligned in a line in the X-axis direction. The plurality of electrode pads 412i are electrically connected to the plurality of substrate electrodes 26b, respectively, through the bonding wire 81d.

The CMOS chip 412g is affixed to the lower surface of the memory chip 412f. The CMOS chip 412g has the same configuration as that of the CMOS chip 412b rotated by 180° with the Z axis as a rotation axis.

In the present embodiment, the three plate-shaped portions 415 have the same configuration as that of the three plate-shaped portions 413 rotated by 180° with the Z axis as a rotation axis.

Specifically, the three plate-shaped portions 415 are provided on the side of the Y-axis+direction of the three plate-shaped portions 413. The plate-shaped portions 415 have a width W1 in the Y-axis direction. Note that the width W1 of each plate-shaped portion 415 may vary within a range of manufacturing tolerances.

Each plate-shaped portion 415 includes a memory chip 415a (an example of a “sixth memory chip”), a CMOS chip 415b (an example of the “second semiconductor chip”), mold resin 415c (an example of the “resin layer”), and a plurality of electrode pads 415d (an example of “sixth electrode pads”).

The memory chip 415a, the CMOS chip 415b, the mold resin 415c, the electrode pads 415d, and the die attachment films 425 are similar to the memory chip 411a, the CMOS chip 411b, the mold resin 411c, the electrode pads 411d, and the die attachment films 421 in each plate-shaped portion 411, respectively.

The memory chip 415a is located closer to an end portion of the plate-shaped portion 415 on the side of the Y-axis+direction than to an end portion of the plate-shaped portion 415 on the side of the Y-axis−direction. The upper surface of the memory chip 415a is provided with the same number of electrode pads 415d as the number of substrate electrodes 26b that form the bonding finger.

The plurality of electrode pads 415d are located closer to an end of the memory chip 415a on the side of the Y-axis+direction than to an end thereof on the side of the Y-axis−direction and are aligned in a line in the X-axis direction. The plurality of electrode pads 415d are electrically connected to the plurality of substrate electrodes 26b, respectively, through the bonding wire 81d.

The three plate-shaped portions 415 are laminated in the up-down direction above the plate-shaped portion 412 and on the side of the Y-axis+direction of the three plate-shaped portions 413. Specifically, the lowermost plate-shaped portion 415 is connected to the upper surface of the plate-shaped portion 412 by the die attachment film 425. The second plate-shaped portion 415 from the bottom is connected to the upper surface of the lowermost plate-shaped portion 415 by a die attachment film 425. In this manner, the three plate-shaped portions 415 are laminated to form the laminated body 402.

The side of the Y-axis+direction of the laminated body 402 has a stepped shape. The steps have step surfaces (terrace surfaces) SP4 parallel to the XY plane. The electrode pads 412i or 415d are located on the stepped surfaces SP4.

In a plan view of the surface 25a of the wiring substrate 25, an end portion 402b of the laminated body 402 on the side of the Y-axis+direction is located closer to the side of the Y-axis+direction than an end portion 403a of the laminated body 403 on the side of the Y-axis+direction.

### [Method of Manufacturing Semiconductor Device 12]

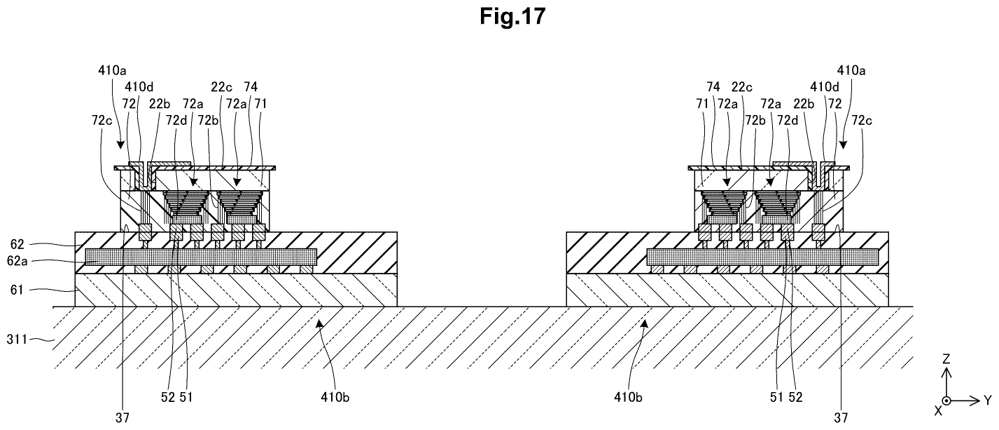

As a method of manufacturing the semiconductor device 12, first, a CMOS chip 410b on the side of the Y-axis−direction and a CMOS chip 410b on the side of the Y-axis+direction are placed on a silicon wafer 311 such that the orientation of one of them is the same as the orientation of the other one rotated by 180° with the Z axis as a rotation axis at the time of the placement as illustrated in FIG. 17.

Specifically, the electrode pads 410d are located on the side of the Y-axis−direction in the CMOS chip 410b on the side of the Y-axis−direction. On the other hand, the electrode pads 410d are located on the side of the Y-axis+direction in the CMOS chip 410b on the side of the Y-axis+direction.

Next, processing similar to the processing illustrated in FIGS. 6 to 11 is performed.

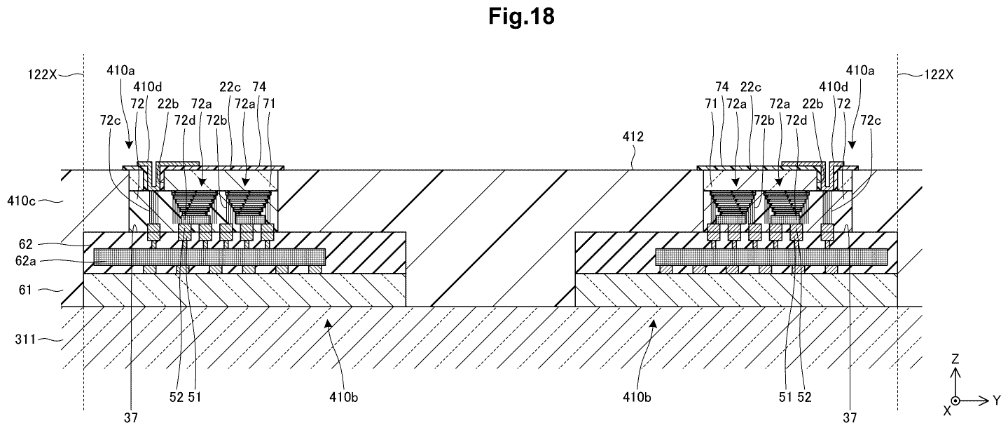

Next, the silicon wafer 311 is diced along dicing lines 122X, and a part of the silicon wafer 311 is separated into the plate-shaped portion 412 by performing chemical mechanical polishing on the lower surface of the separated silicon wafer 311, as illustrated in FIG. 18 (see FIG. 16).

The separated memory chip 410a on the side of the Y-axis−direction and the memory chip 410a on the side of the Y-axis+direction are the memory chips 412a and 412f, respectively.

The separated CMOS chip 410b on the side of the Y-axis−direction and the CMOS chip 410b on the side of the Y-axis+direction are the CMOS chips 412b and 412g, respectively.

The separated electrode pads 410d on the side of the Y-axis−direction and the electrode pads 410d on the side of the Y-axis+direction are electrode pads 412d and 412i, respectively.

### Effects

In this manner, it is possible to enhance rigidity against warpage of the wiring substrate 25 and to thereby curb warpage of the wiring substrate 25 with the configuration in which the plate-shaped portion 412 in the laminated body 402 is provided over the upper surface of the laminated body 401 and the upper surface of the laminated body 403. Therefore, it is possible to provide a semiconductor device capable of improving quality.

### First Modification of Semiconductor Device 12

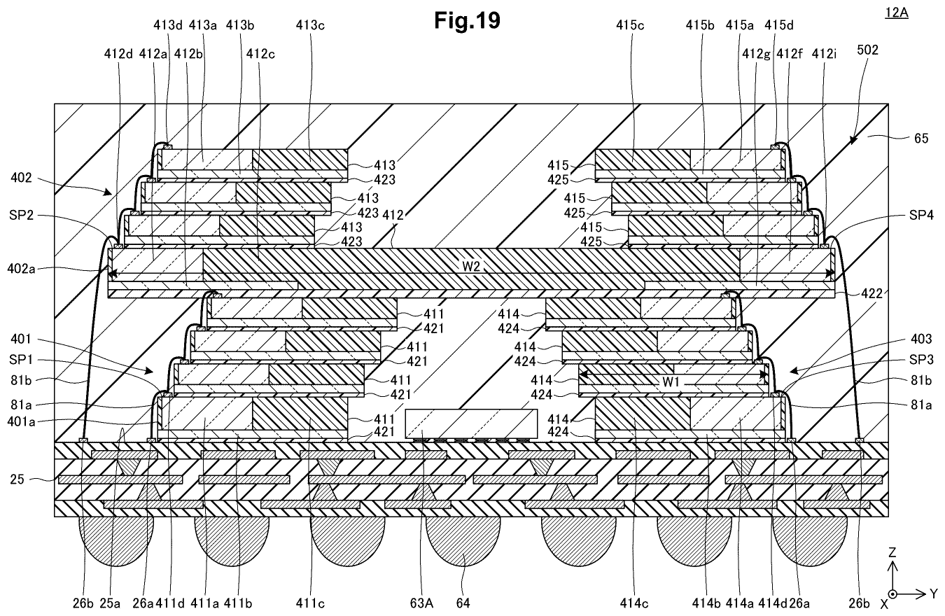

FIG. 19 is a schematic diagram illustrating a section of a semiconductor device according to a first modification of the second embodiment. As illustrated in FIG. 19, a semiconductor device 12A, which is the first modification of the semiconductor device 12, differs from the semiconductor device 12 illustrated in FIG. 16 in that the semiconductor device 12A further includes a controller chip 63A (an example of a “first semiconductor chip”) that is connected to the surface 25a of the wiring substrate 25 between the laminated body 401 and the laminated body 403.

The controller chip 63A is flip-chip-connected to the wiring substrate 25, for example, and is electrically connected to the wiring substrate 25. The controller chip 63A controls, for example, the CMOS chips 411b, 412b, 412g, 413b, 414b, and 415b.

The configuration in which the side of the Y-axis−direction of the laminated body 401 and the side of the Y-axis+direction of the laminated body 403 have stepped shapes forms a space spreading downward between the laminated body 401 and the laminated body 402. With a configuration in which the controller chip 63A is disposed in such a space, it is possible to effectively use the space in the semiconductor device 12A and to implement the semiconductor device 12A in a compact size.

### Second Modification of Semiconductor Device 12

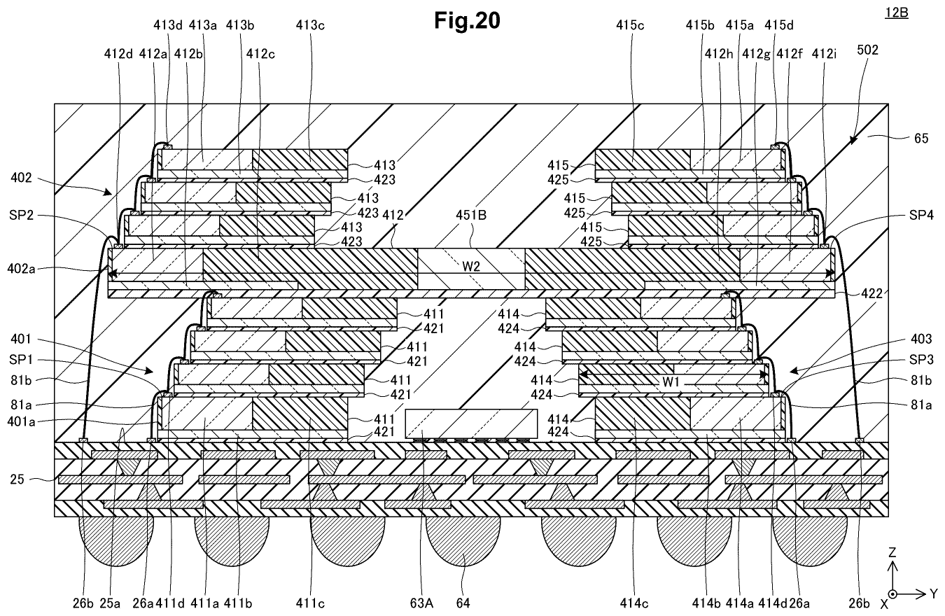

FIG. 20 is a schematic diagram illustrating a section of a semiconductor device according to a second modification of the second embodiment. As illustrated in FIG. 20, a semiconductor device 12B, which is the second modification of the semiconductor device 12, differs from the semiconductor device 12A illustrated in FIG. 19 in that the plate-shaped portion 412 further includes mold resin 412h (an example of a “third resin layer”) connected to the memory chip 412f on the side of the Y-axis−direction and a semiconductor layer 451B (an example of a “first semiconductor layer”) connected to the mold resin 412c on the side of the Y-axis+direction and the mold resin 412h on the side of the Y-axis−direction.

The semiconductor layer 451B contains, for example, silicon. The semiconductor layer 451B is, for example, a spacer. Rigidity of the semiconductor layer 451B is higher than rigidity of the mold resins 412c and 412h. Note that the semiconductor layer 451B may be formed of a material that is not a semiconductor as long as the material has high rigidity and does not electrically interfere with other chips.

With such a configuration in which the semiconductor layer 451B is provided between the memory chip 412a and the CMOS chip 412b and between the memory chip 412f and the CMOS chip 412g, it is possible to enhance flexural rigidity of the plate-shaped portion 412. It is thus possible to effectively curb warpage of the wiring substrate 25.

### Third Modification of Semiconductor Device 12

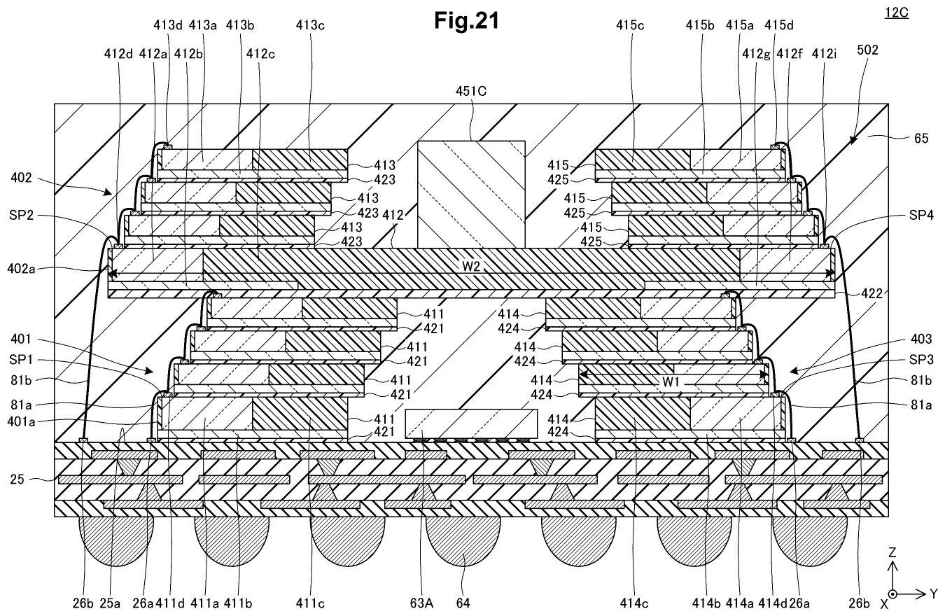

FIG. 21 is a schematic diagram illustrating a section of a semiconductor device according to a third modification of the second embodiment. As illustrated in FIG. 21, a semiconductor device 12C, which is the third modification of the semiconductor device 12, differs from the semiconductor device 12A illustrated in FIG. 19 in that the semiconductor device 12C further includes a semiconductor layer 451C (an example of the “first semiconductor layer”) provided above the mold resin 412c.

The semiconductor layer 451C is similar to the semiconductor layer 451B. In the present modification, a lower surface of the semiconductor layer 451C is in contact with the upper surface of the mold resin 412c. It is thus possible to curb bending deformation of the mold resin 412c. In other words, it is possible to enhance flexural rigidity of the plate-shaped portion 412 and to thereby effectively curb warpage of the wiring substrate 25.

Note that a configuration in which the semiconductor layer 451B illustrated in FIG. 20 is provided below the semiconductor layer 451C may also be adopted.

### Fourth Modification of Semiconductor Device 12

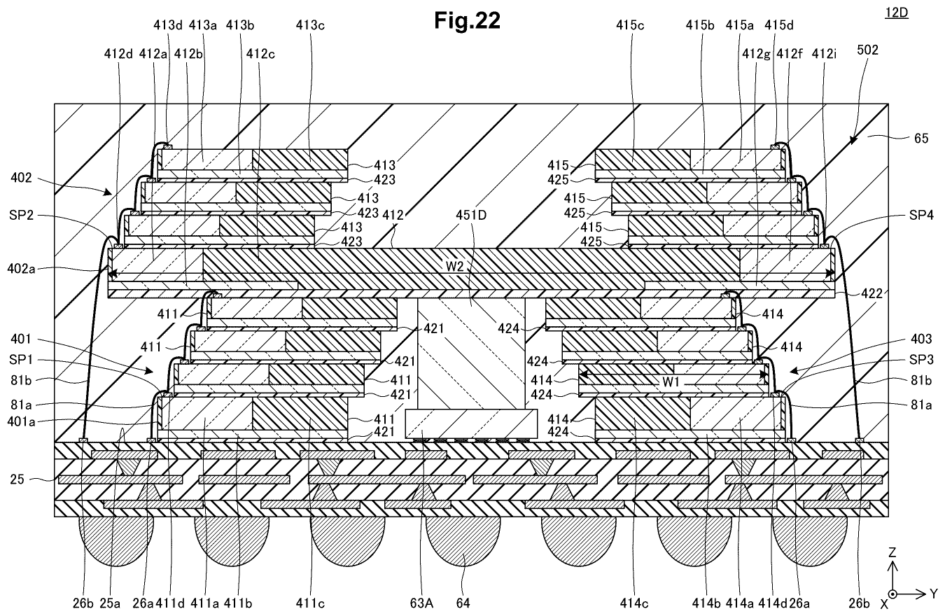

FIG. 22 is a schematic diagram illustrating a section of a semiconductor device according to a fourth modification of the second embodiment. As illustrated in FIG. 22, a semiconductor device 12D, which is the fourth modification of the semiconductor device 12, differs from the semiconductor device 12A illustrated in FIG. 19 in that the semiconductor device 12D further includes a semiconductor layer 451D (an example of the “first semiconductor layer”) provided below the mold resin 412c.

The semiconductor layer 451D is similar to the semiconductor layer 451B. In the present modification, an upper surface of the semiconductor layer 451D is in contact with the die attachment film 422. A lower surface of the semiconductor layer 451D is connected to the upper surface of the controller chip 63A via a die attachment film, which is not illustrated, for example.

It is thus possible to curb bending deformation of the mold resin 412c. In other words, it is possible to enhance flexural rigidity of the plate-shaped portion 412 and to thereby effectively curb warpage of the wiring substrate 25.

Note that a configuration in which at least one of the semiconductor layer 451B (see FIG. 20) and the semiconductor layer 451C (see FIG. 21) is provided above the semiconductor layer 451D may also be adopted.

### Fifth Modification of Semiconductor Device 12

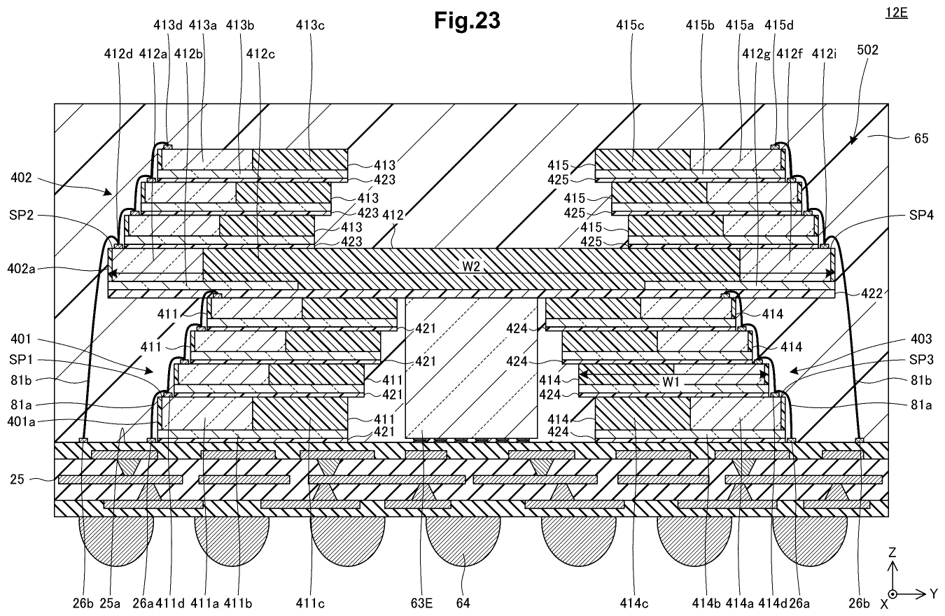

FIG. 23 is a schematic diagram illustrating a section of a semiconductor device according to a fifth modification of the second embodiment. As illustrated in FIG. 23, a semiconductor device 12E, which is the fifth modification of the semiconductor device 12, differs from the semiconductor device 12A illustrated in FIG. 19 in that an upper surface of a controller chip 63E is in contact with the die attachment film 422.

The semiconductor device 12E includes the controller chip 63E instead of the controller chip 63A as compared with the semiconductor device 12A illustrated in FIG. 19. The height of the controller chip 63E in the up-down direction is higher than the height of the controller chip 63A in the up-down direction. The upper surface of the controller chip 63E is aligned with the upper surface of the laminated body 401 and the upper surface of the laminated body 403.

With such a configuration, it is possible to curb bending deformation of the mold resin 412c. In other words, it is possible to enhance flexural rigidity of the plate-shaped portion 412 and to thereby effectively curb warpage of the wiring substrate 25.

### Sixth Modification of Semiconductor Device 12

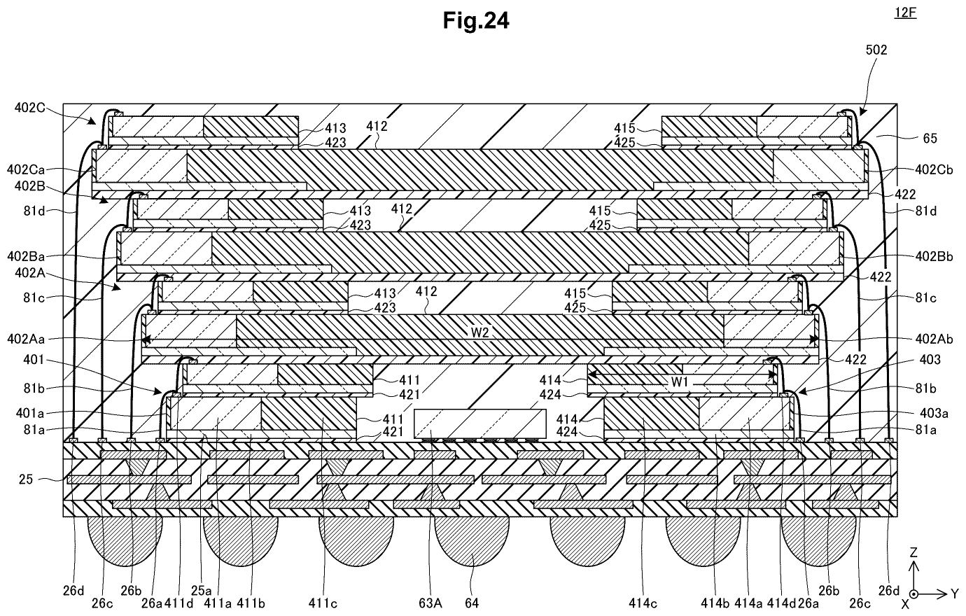

FIG. 24 is a schematic diagram illustrating a section of a semiconductor device according to a sixth modification of the second embodiment. As illustrated in FIG. 24, a semiconductor device 12F, which is the sixth modification of the semiconductor device 12, differs from the semiconductor device 12A illustrated in FIG. 19 in that a plurality of laminated bodies 402 are laminated.

A two-tower coupled structure 502 in the semiconductor device 12F includes laminated bodies 402A, 402B, and 402C instead of the laminated body 402 and further includes bonding wires 81c and 81d as compared with the two-tower coupled structure 502 in the semiconductor device 12A illustrated in FIG. 19.

The laminated bodies 402A, 402B, and 402C are examples of the laminated bodies 402. In the present modification, two plate-shaped portions 411 and two plate-shaped portions 414 are laminated in the laminated bodies 401 and 403, respectively. Note that a configuration in which three or more plate-shaped portions 411 are laminated in the laminated body 401 may also be adopted. At this time, the same number of plate-shaped portions 414 as the number of plate-shaped portions 411 in the laminated body 401 are laminated in the laminated body 403.

The laminated bodies 402A, 402B, and 402C are laminated in this order from the lower side to the upper side. In the laminated bodies 402A, 402B, and 402C, the plate-shaped portions 413 and 415 are laminated on the side of the Y-axis−direction and on the side of the Y-axis+direction, respectively, on the upper surface of the plate-shaped portions 412.

Note that a configuration in which two or more plate-shaped portions 413 are laminated on the side of the Y-axis−direction on the upper surfaces of the plate-shaped portions 412 in the laminated bodies 402A, 402B, and 402C may also be adopted. At this time, the same number of plate-shaped portions 415 as the number of plate-shaped portions 413 are laminated on the side of the Y-axis+direction.

In addition, the number of plate-shaped portions 413 laminated in the laminated body 402A, the number of plate-shaped portions 413 laminated in the laminated body 402B, and the number of plate-shaped portions 413 laminated in the laminated body 402C may be partially the same or may be different from each other.

The width of the laminated body 402A in the Y-axis direction, the width of the laminated body 402B in the Y-axis direction, and the width of the laminated body 402C in the Y-axis direction are wider in this order.

In a plan view of the surface 25a of the wiring substrate 25, an end portion 402Ca of the laminated body 402C on the side of the Y-axis−direction, an end portion 402Ba of the laminated body 402B on the side of the Y-axis−direction, and an end portion 402Aa of the laminated body 402A on the side of the Y-axis−direction are located on the side of the Y-axis−direction as compared with the end portion 402Ba, the end portion 402Aa, and the end portion 401a of the laminated body 401 on the side of the Y-axis−direction, respectively.

In a plan view of the surface 25a of the wiring substrate 25, an end portion 402Cb of the laminated body 402C on the side of the Y-axis+direction, an end portion 402Bb of the laminated body 402B on the side of the Y-axis+direction, and an end portion 402Ab of the laminated body 402A on the side of the Y-axis+direction are located on the side of the Y-axis+direction as compared with the end portion 402Bb, the end portion 402Ab, and the end portion 403a of the laminated body 403 on the side of the Y-axis+direction, respectively.

With such a configuration, it is possible to increase the inter-electrode intervals of the substrate electrodes 26a to 26d in the Y-axis direction without increasing the lengths of the bonding wires 81a to 81d. It is thus possible to reduce the density of the substrate electrodes 26a to 26d.

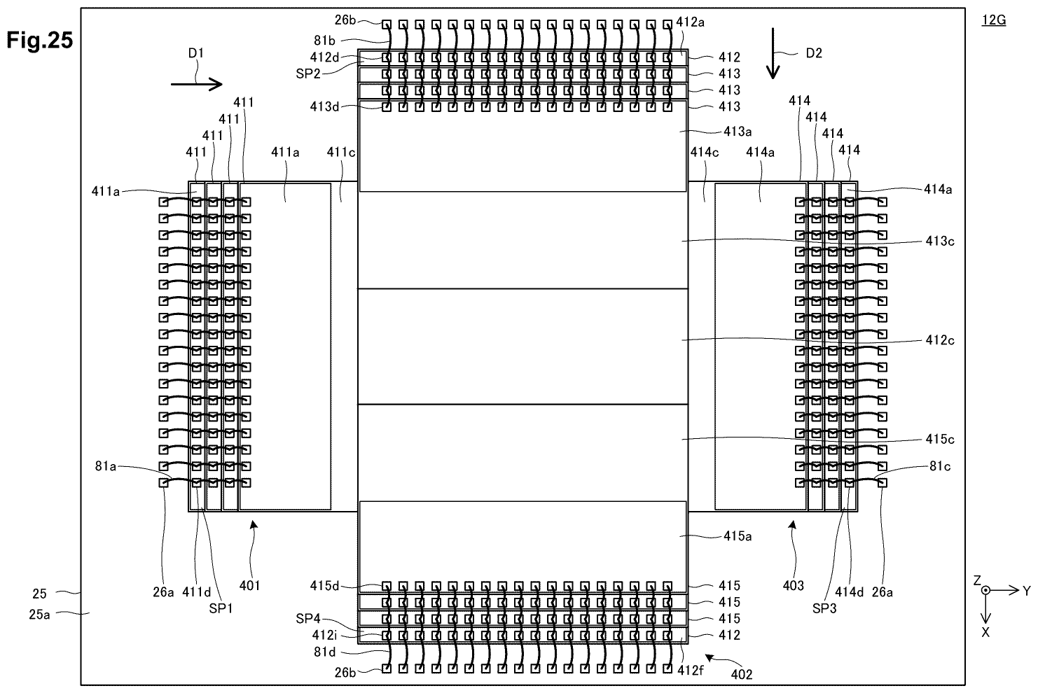

(Seventh Modification of Semiconductor Device 12) FIG. 25 is a schematic diagram illustrating a section of a semiconductor device according to a seventh modification of the second embodiment. As illustrated in FIG. 25, a semiconductor device 12G, which is the seventh modification of the semiconductor device 12, differs from the semiconductor device 12 illustrated in FIG. 16 in that a width direction D1 (an example of the “first width direction”) in which the laminated bodies 401 and 403 are aligned and a width direction D2 (an example of a “second width direction”) in which the plate-shaped portions 413 and 415 are aligned in the laminated body 402 substantially perpendicularly intersect each other.

In the present modification, the width directions D1 and D2 are substantially parallel to the Y-axis direction and the X-axis direction, respectively.

The three plate-shaped portions 413 are laminated in the up-down direction on the side of the X-axis−direction (an example of a “fourth side”) and three plate-shaped portions 415 are laminated in the up-down direction on the side of the X-axis+direction (an example of a “third side”) on the upper surface of the plate-shaped portion 412.

The plurality of substrate electrodes 26b that form the bonding finger are provided on the side of the X-axis+direction and on the side of the X-axis−direction of the laminated body 402.

The side of the X-axis−direction of the laminated body 402 has a stepped shape. The steps have step surfaces SP2 parallel to the XY plane. The electrode pads 412d or 413d are located on the step surface SP2.

The side of the X-axis+direction of the laminated body 402 has a stepped shape. The steps have step surfaces SP4 parallel to the XY plane. The electrode pads 412i or 415d are located on the stepped surfaces SP4.

Note that although the configuration in which the width direction D1 and the width direction D2 substantially perpendicularly intersect each other has been described in the present modification, the present invention is not limited thereto. A configuration in which the angle formed between the width direction D1 and the width direction D2 is an arbitrary angle may be adopted as long as the angle is greater than 0° and less than 180°.

### Third Embodiment

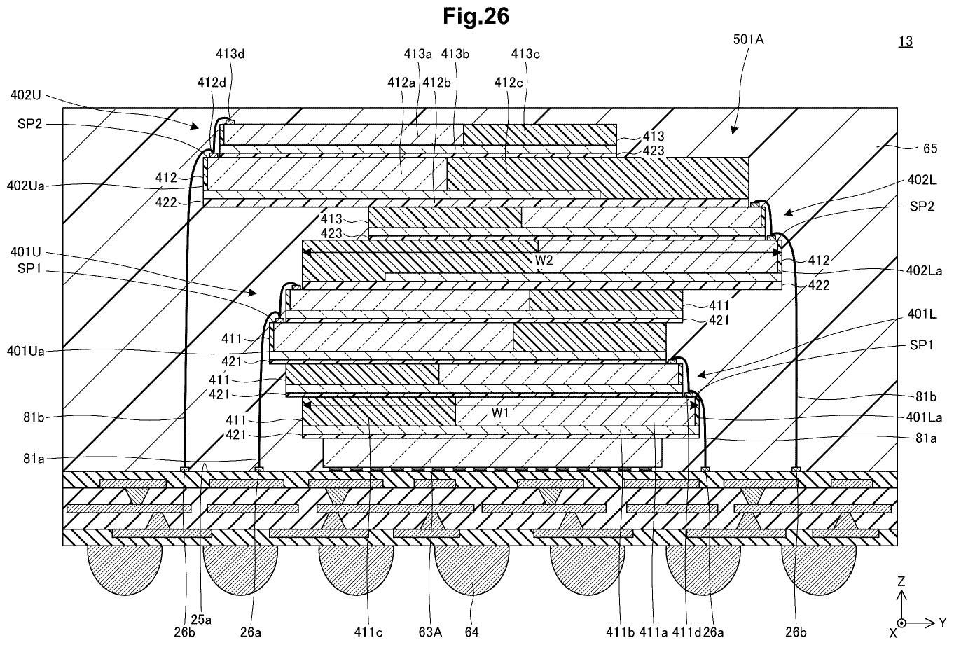

A semiconductor device according to a third embodiment will be described. FIG. 26 is a schematic diagram illustrating a section of the semiconductor device according to the third embodiment. Note that how to interpret FIG. 26 is similar to that of FIG. 1.

As illustrated in FIG. 26, a semiconductor device 13 differs from the semiconductor device 11 according to the first embodiment in that the laminated bodies 401 and 402 are disposed on the lower side and the upper side, respectively, and the two one-tower structures 501 are laminated in the up-down direction to form a one-tower structure 501A as compared with the semiconductor device 11 illustrated in FIG. 1.

The semiconductor device 13 includes the one-tower structure 501A instead of the two one-tower structures 501 as compared with the semiconductor device 11 illustrated in FIG. 1.

The one-tower structure 501A includes the controller chip 63A, laminated bodies 401L and 401U, and laminated bodies 402L and 402U.

The laminated bodes 401L and 401U are examples of the laminated body 401. In the present embodiment, two plate-shaped portions 411 are laminated in each of the laminated bodies 401L and 401U. Note that a configuration in which three or more plate-shaped portions 411 are laminated in each of the laminated bodies 401L and 401U may also be adopted.

The laminated bodies 402L and 402U are examples of the laminated body 402. In the present embodiment, the plate-shaped portions 412 and 413 are laminated in the laminated bodies 402L and 402U, respectively. Note that a configuration in which the plate-shaped portion 412 and a plurality of plate-shaped portions 413 are laminated in each of the laminated bodies 402L and 402U may also be adopted.

The controller chip 63A, the laminated bodies 401L, 401U, 402L, and 402U are laminated in this order from the lower side to the upper side.

The side of the Y-axis+direction of the laminated body 401L and the laminated body 402L has a stepped shape. The side of the Y-axis−direction of the laminated body 401U and the laminated body 402U has a stepped shape.

In a plan view of the surface 25a of the wiring substrate 25, an end portion 402La of the laminated body 402L on the side of the Y-axis+direction is located on the side of the Y-axis+direction as compared with an end portion 401La of the laminated body 401L on the side of the Y-axis+direction.

In a plan view of the surface 25a of the wiring substrate 25, an end portion 402Ua of the laminated body 402U on the side of the Y-axis−direction is located on the side of the Y-axis−direction as compared with an end portion 401Ua of the laminated body 401U on the side of the Y-axis−direction.

### Fourth Embodiment

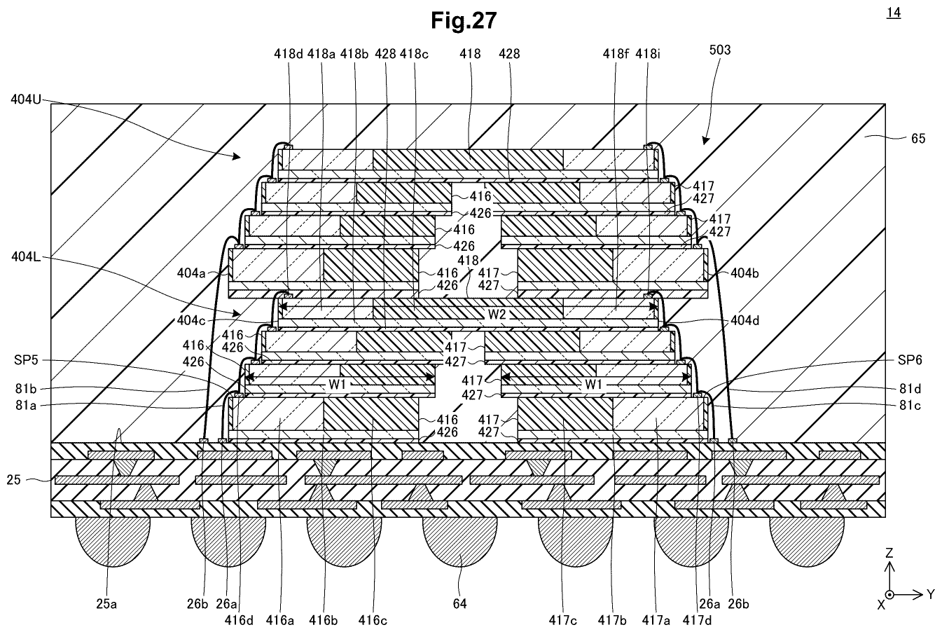

A semiconductor device according to a fourth embodiment will be described. FIG. 27 is a schematic diagram illustrating a section of the semiconductor device according to the fourth embodiment. Note that how to interpret FIG. 27 is similar to that of FIG. 1.

As illustrated in FIG. 27, a semiconductor device 14 differs from the semiconductor device 11 according to the first embodiment in that two laminated bodies 401 with mutually opposite orientations are combined to form a laminated body 404 as compared with the semiconductor device 11 illustrated in FIG. 1.

The semiconductor device 14 includes a two-tower coupled structure 503 instead of the two one-tower structures 501 as compared with the semiconductor device 11 illustrated in FIG. 1.

The two-tower coupled structure 503 includes bonding wires 81a, 81b, 81c, and 81d and laminated bodies 404L and 404U. Hereinafter, each of the laminated bodies 404L and 404U may be referred to as a laminated body 404 (an example of a “fourth laminated body”).

The laminated body 404L includes L (L is an integer of equal to or greater than one) plate-shaped portions 416 (an example of “sixth plate-shaped portions”), L plate-shaped portions 417 (an example of “seventh plate-shaped portions”), a plate-shaped portion 418 (an example of a “eighth plate-shaped portion”), L die attachment films 426, L die attachment films 427, and a die attachment film 428.

The laminated body 404U includes K (K is an integer of equal to or greater than one) plate-shaped portions 416 (an example of the “ninth plate-shaped portions”), K plate-shaped portions 417 (an example of the “tenth plate-shaped portions”), a plate-shaped portion 418 (an example of the “eleventh plate-shaped portions”), K die attachment films 426, K die attachment films 427, and a die attachment film 428.

In the present embodiment, each of the laminated bodies 404L and 404U includes three plate-shaped portions 416, three plate-shaped portions 417, a plate-shaped portion 418, three die attachment films 426, three die attachment films 427, and a die attachment film 428.

The laminated body 404U is laminated above the laminated body 404L. Although the laminated body 404L on the lower side will be described below as a representative, the same applies to the laminated body 404U on the upper side.

The plate-shaped portions 416 have a width W1 in the Y-axis direction. Each plate-shaped portion 416 includes a memory chip 416a (an example of a “seventh memory chip” and an “eleventh memory chip”), a CMOS chip 416b (an example of the “second semiconductor chip”), mold resin 416c (an example of the “resin layer”), and a plurality of electrode pads 416d.

The memory chip 416a, the CMOS chip 416b, the mold resin 416c, the electrode pads 416d, and the die attachment films 426 are similar to the memory chip 411a, the CMOS chip 411b, the mold resin 411c, the electrode pads 411d, and the die attachment films 421 in each plate-shaped portion 411.

The memory chip 416a is located closer to an end portion of the plate-shaped portion 416 on the side of the Y-axis−direction than an end portion of the plate-shaped portion 416 on the side of the Y-axis+direction. An upper surface of the memory chip 416a is provided with the same number of electrode pads 416d as the number of substrate electrodes 26a that form a bonding finger.

The plurality of electrode pads 416d are located closer to an end portion of the memory chip 416a on the side of the Y-axis−direction than to an end thereof on the side of the Y-axis+direction and are aligned in a line in the X-axis direction. The plurality of electrode pads 416d are electrically connected to the plurality of substrate electrodes 26a, respectively, through the bonding wire 81a.

The three plate-shaped portions 416 are laminated in the up-down direction above the wiring substrate 25. Specifically, the lowermost plate-shaped portion 416 is connected to the surface 25a of the wiring substrate 25 by a die attachment film 426 with a width W1 in the Y-axis direction, for example. The second plate-shaped portion 416 from the bottom is connected to the upper surface of the lowermost plate-shaped portion 416 by a die attachment film 426. In this manner, the three plate-shaped portions 416 are laminated.

The three plate-shaped portions 417 have the same configuration as that of the three plate-shaped portions 416 rotated by 180° with the Z axis as a rotation axis.

Each plate-shaped portion 417 includes a memory chip 417a (an example of an “eighth memory chip” and a “twelfth memory chip”), a CMOS chip 417b (an example of the “second semiconductor chip”), mold resin 417c (an example of the “resin layer”), and a plurality of electrode pads 417d.

The memory chip 417a, the CMOS chip 417b, the mold resin 417c, the electrode pads 417d, and the die attachment films 427 are the same as the memory chip 411a, the CMOS chip 411b, the mold resin 411c, the electrode pads 411d, and the die attachment films 421 in each plate-shaped portion 411, respectively.

The memory chip 417a is located closer to an end portion of the plate-shaped portion 417 on the side of the Y-axis+direction than an end portion of the plate-shaped portion 417 on the side of the Y-axis−direction. An upper surface of the memory chip 417a is provided with the same number of electrode pads 417d as the number of substrate electrodes 26a that form the bonding finger.

The plurality of electrode pads 417d are located closer to an end of the memory chip 417a on the side of the Y-axis+direction than to an end thereof on the side of the Y-axis−direction and are aligned in a line in the X-axis direction. The plurality of electrode pads 417d are electrically connected to the plurality of substrate electrodes 26a, respectively, through the bonding wire 81c.

The three plate-shaped portions 417 are laminated in the up-down direction on the side of the Y-axis+direction of the three plate-shaped portions 416. Specifically, the lowermost plate-shaped portion 417 is connected to the surface 25a of the wiring substrate 25 by a die attachment film 427 with a width W1 in the Y-axis direction, for example. The second plate-shaped portion 417 from the bottom is connected to the upper surface of the lowermost plate-shaped portion 417 by a die attachment film 427. In this manner, the three plate-shaped portions 417 are laminated.

The plate-shaped portion 418 includes a memory chip 418a (an example of a “ninth memory chip” and a “thirteenth memory chip”) and 418f (an example of a “tenth memory chip” and a “fourteenth memory chip”), a CMOS chip 418b (an example of the “second semiconductor chip”), mold resin 418c (an example of a “fourth resin layer” and a “fifth resin layer”), and a plurality of electrode pads 418d and 418i.

The plate-shaped portion 418 has a width W2. The plate-shaped portion 418 is provided over the upper surface of the uppermost plate-shaped portion 416 and the upper surface of the uppermost plate-shaped portion 417.

The die attachment film 428 is provided between the plate-shaped portion 418 and the uppermost plate-shaped portions 416 and 417. Specifically, the upper surface of the die attachment film 428 is in contact with the lower surface of the plate-shaped portion 418. The lower surface of the die attachment film 428 is in contact with the upper surface of the uppermost plate-shaped portion 416 and the upper surface of the uppermost plate-shaped portion 417.

The memory chip 418a is a memory chip similar to the memory chip 412a (see FIG. 1). The memory chip 418a is located closer to an end portion of the plate-shaped portion 418 on the side of the Y-axis−direction than to an end portion of the plate-shaped portion 418 on the side of the Y-axis+direction.

An upper surface of the memory chip 418a is provided with the same number of electrode pads 418d as the number of substrate electrodes 26a that form the bonding finger.

The plurality of electrode pads 418d are located closer to an end of the memory chip 418a on the side of the Y-axis−direction than to an end thereof on the side of the Y-axis+direction and are aligned in a line in the X-axis direction. The plurality of electrode pads 418d are electrically connected to the plurality of substrate electrodes 26a, respectively, through the bonding wire 81a.

The mold resin 418c is connected to the memory chip 418a on the side of the Y-axis+direction. The memory chip 418f is located closer to an end portion of the plate-shaped portion 418 on the side of the Y-axis+direction than to an end portion of the plate-shaped portion 418 on the side of the Y-axis−direction and is connected to the mold resin 418c on the side of the Y-axis+direction.

The memory chip 418f has the same configuration as that of the memory chip 418a rotated by 180° with the Z axis as a rotation axis.

An upper surface of the memory chip 418f is provided with the same number of electrode pads 418i as the number of substrate electrodes 26a that form the bonding finger.

The plurality of electrode pads 418i are located closer to an end of the memory chip 418f on the side of the Y-axis+direction than to an end thereof on the side of the Y-axis−direction and are aligned in a line in the X-axis direction. The plurality of electrode pads 418i are electrically connected to the plurality of substrate electrodes 26a, respectively, through the bonding wire 81c.

The CMOS chip 418b is a chip in which CMOS chips 412b and 412g (see FIG. 16) are integrated. The CMOS chip 418b controls the memory chips 418a and 418f. The width of the CMOS chip 418b in the Y-axis direction is about double the width of the CMOS chip 412b or 412g in the Y-axis direction. The memory chips 418a and 418f are affixed to an affixed surface on the side of the Y-axis−direction and an affixed surface on the side of the Y-axis+direction of the upper surface of the CMOS 418b, respectively.

The mold resin 418c is connected to the upper surface of the CMOS chip 418b except for the affixed surfaces and side surfaces parallel to the ZX plane and side surfaces parallel to the YZ plane of the memory chips 418a and 418f.

A die attachment film 428 having a width W2 is provided on the lower surface of the CMOS chip 418b.

The lowermost plate-shaped portion 416 and the lowermost plate-shaped portion 417 in the laminated body 404U are connected to the upper surface of the plate-shaped portion 418 in the laminated body 404L by the die attachment films 426 and 427, respectively.

The side of the Y-axis+direction of the laminated bodies 404L and 404U has a stepped shape. The side of the Y-axis−direction of the laminated body 404L and the laminated body 404U has a stepped shape.

In a plan view of the surface 25a of the wiring substrate 25, an end portion 404a of the lowermost plate-shaped portion 416 on the side of the Y-axis−direction in the laminated body 404U is located on the side of the Y-axis−direction as compared with an end portion 404c of the plate-shaped portion 418 on the side of the Y-axis−direction in the laminated body 404L.

In a plan view of the surface 25a of the wiring substrate 25, an end portion 404b of the lowermost plate-shaped portion 417 on the side of the Y-axis+direction in the laminated body 404U is located closer to the Y-axis+direction as compared with an end portion 404d of the plate-shaped portion 418 on the side of the Y-axis+direction in the laminated body 404L.

Although the configuration in which the number of laminated plate-shaped portions 416 in the laminated body 401L and the number of laminated plate-shaped portions 416 in the laminated body 401U are the same has been described, the present invention is not limited thereto. A configuration in which the number of laminated plate-shaped portions 416 in the laminated body 401L and the number of laminated plate-shaped portions 416 in the laminated body 401U are different from each other may also be adopted.

Moreover, a configuration in which the semiconductor layer 451B (see FIG. 20) is provided between the memory chip 418a and the memory chip 418f in the plate-shaped portion 418 may also be adopted.

### [Method of Manufacturing Semiconductor Device 14]

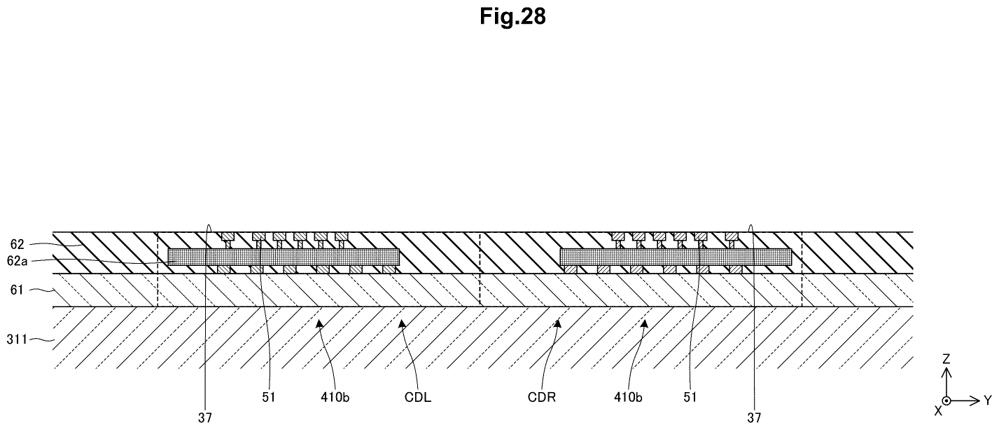

As a method of manufacturing the semiconductor device 14, first, dies of a plurality of CMOS chips 410b aligned in the Y-axis direction are formed on an upper surface of a silicon wafer 311 as illustrated in FIG. 28.

In the dies of two CMOS chips 410b that are adjacent to each other in the Y-axis direction, the die of the CMOS chip 410b on the side of the Y-axis−direction (hereinafter, referred to as a CMOS die CDL in some cases) is formed to be the same as the die of the CMOS chip 410b on the side of the Y-axis+direction (hereinafter, referred to as a CMOS die CDR in some cases) rotated by 180° with the Z axis as a rotation axis.

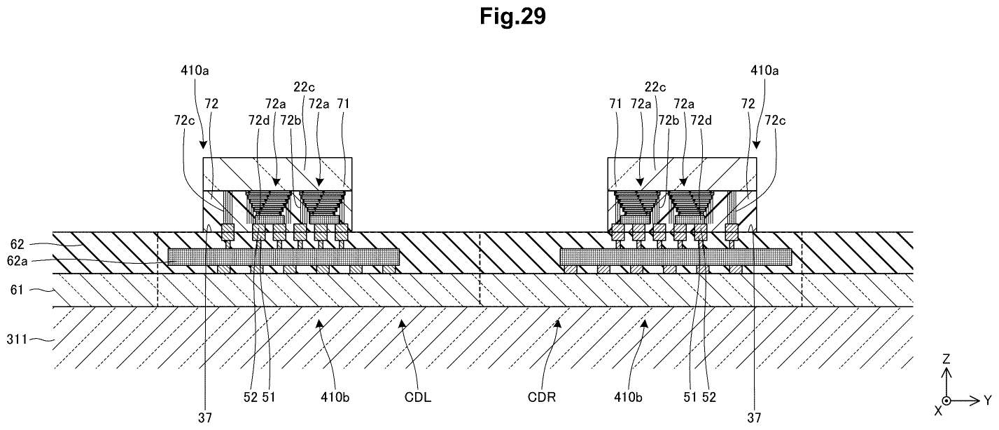

Next, two memory chips 410a are affixed to the CMOS dies CDL and CDR, respectively, as illustrated in FIG. 29. At this time, the orientation of one of the two memory chips 410a is the same as the orientation of the other rotated by 180° with the Z axis as a rotation axis.

Specifically, the memory chip 410a is affixed such that a via 72c connected to electrode pads 410d is located on the side of the Y-axis−direction in the CMOS die CDL on the side of the Y-axis−direction. On the other hand, the memory chip 410a is affixed such that the via 72c connected to the electrode pads 410d is located on the side of the Y-axis+direction in the CMOS die CDR on the side of the Y-axis+direction.

Next, processing similar to the processing illustrated in FIGS. 6 to 11 is performed.

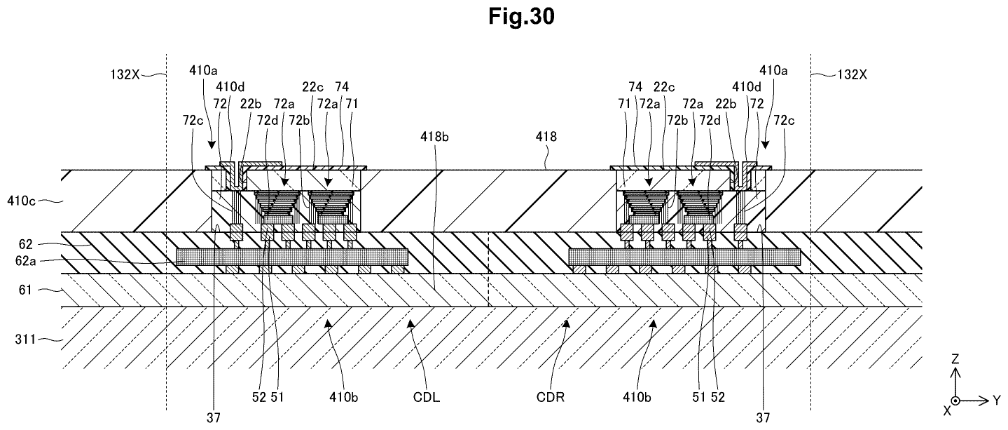

Next, the silicon wafer 311 is diced along dicing lines 132X, and a part of the silicon wafer 311 is separated into the plate-shaped portion 418 (see FIG. 27) by performing chemical mechanical polishing on the lower surface of the separated silicon wafer 311 as illustrated in FIG. 30.

The separated memory chip 410a on the side of the Y-axis−direction and the memory chip 410a on the side of the Y-axis+direction are the memory chips 418a and 418f, respectively.

The CMOS dies CDL and CDR are separated while remaining integrated and are caused to serve as the CMOS chip 418b.

The separated electrode pads 410d on the side of the Y-axis−direction and the electrode pads 410d on the side of the Y-axis+direction are electrode pads 418d and 418i, respectively.
(a) Although the configuration in which each plate-shaped portion 411 includes the memory chip 411a that is a NAND-type flash memory chip and the CMOS chip 411b that controls the memory chip 411a has been described in the embodiments, the present invention is not limited thereto. Each plate-shaped portion 411 may include a chip of volatile memory such as a dynamic random access memory (DRAM) instead of the memory chip 411a. Furthermore, the plate-shaped portion 411 may include both a chip of a non-volatile memory and a chip of a volatile memory. In addition, each CMOS chip 411b may be a chip that includes a central processing unit (CPU) with a computing function and a control function. The same applies to the plate-shaped portions 412 to 418.
(b) A semiconductor device including:
a wiring substrate that has a main surface intersecting an up-down direction;
a first laminated body that includes N first plate-shaped portions having a first width in a first width direction intersecting the up-down direction, the N first plate-shaped portions being laminated in the up-down direction above the wiring substrate; and
a second laminated body that includes (i) a second plate-shaped portion having a second width that is wider than the first width in the first width direction and provided above the first laminated body, and (ii) M third plate-shaped portions provided above the second plate-shaped portion and having the first width in the first width direction, the second plate-shaped portion and the M third plate-shaped portions being laminated in the up-down direction,
in which the first plate-shaped portions include first memory chips,
the second plate-shaped portion includes a second memory chip and a first resin layer connected to a first side of the second memory chip in the first width direction,
the third plate-shaped portions include third memory chips,
a second side of the first laminated body opposite to the first side in the first width direction has a stepped shape,
the second side of the second laminated body has a stepped shape, and
in a plan view of the main surface, an end portion of the second laminated body on the second side is located on the second side as compared with an end portion of the first laminated body on the second side.
(c) The semiconductor device further includes a sixth resin layer that has a composition different from a composition of the first resin layer and seals the first laminated body and the second laminated body.

The present embodiments have been described above with reference to the specific examples. However, the present disclosure is not limited to these specific examples. Modifications in design appropriately added to these specific examples by those skilled in the art are also included in the scope of the present disclosure as long as the modifications include features of the present disclosure. The elements, disposition, conditions, shapes, and the like thereof included in each of the aforementioned specific examples are not limited to the illustrated ones and can be appropriately modified. The elements included in each of the aforementioned specific examples can be differently combined in an appropriate manner as long as no technical conflicts arise.

1. A semiconductor device comprising:
a wiring substrate that has a main surface intersecting an up-down direction;
a first laminated body that includes N (N is an integer of equal to or greater than two) first plate-shaped portions having a first width in a first width direction intersecting the up-down direction, the N first plate-shaped portions being laminated in the up-down direction above the wiring substrate; and
a second laminated body that includes (i) a second plate-shaped portion having a second width that is wider than the first width in the first width direction and provided above the first laminated body, and (ii) M (M is an integer of equal to or greater than one) third plate-shaped portions provided above the second plate-shaped portion and having the first width in the first width direction, the second plate-shaped portion and the M third plate-shaped portions being laminated in the up-down direction,
wherein the first plate-shaped portions include first memory chips provided with first electrode pads, which are electrically connected to the wiring substrate through a first bonding wire, on upper surfaces,
the second plate-shaped portion includes a second memory chip provided with second electrode pads, which are electrically connected to the wiring substrate through a second bonding wire, on an upper surface and a first resin layer connected to a first side of the second memory chip in the first width direction,
the third plate-shaped portions include third memory chips provided with third electrode pads, which are electrically connected to the wiring substrate through the second bonding wire, on upper surfaces,
a second side of the first laminated body opposite to the first side in the first width direction has a stepped shape with stepped surfaces where the first electrode pads are located,
the second side of the second laminated body has a stepped shape with stepped surfaces where the second electrode pads or the third electrode pads are located, and
in a plan view of the main surface, an end portion of the second laminated body on the second side is located closer to the second side than an end portion of the first laminated body on the second side.

2. The semiconductor device according to claim 1, wherein the second memory chip is located closer to an end portion of the second plate-shaped portion on the second side than to an end portion of the second plate-shaped portion on the first side.

3. The semiconductor device according to claim 1, further comprising:
a third laminated body that includes N fourth plate-shaped portions having the first width in the first width direction, the N fourth plate-shaped portions being laminated in the up-down direction on the first side of the first laminated body,
wherein the fourth plate-shaped portions include fourth memory chips provided with fourth electrode pads, which are electrically connected to the wiring substrate through a third bonding wire, on upper surfaces,
the first side of the third laminated body has a stepped shape with stepped surfaces where the fourth electrode pads are located, and
the second plate-shaped portion in the second laminated body is provided over an upper surface of the first laminated body and an upper surface of the third laminated body.

4. The semiconductor device according to claim 3,
wherein the second plate-shaped portion further includes a fifth memory chip provided with fifth electrode pads, which are electrically connected to the wiring substrate through a fourth bonding wire, on the upper surface, the fifth memory chip being provided on the first side of the first resin layer,
the second laminated body further includes M fifth plate-shaped portions provided on the first side of the M third plate-shaped portions and having the first width in the first width direction,
the M fifth plate-shaped portions are laminated in the up-down direction,
the fifth plate-shaped portions include sixth memory chips provided with sixth electrode pads, which are electrically connected to the wiring substrate through the fourth bonding wire, on upper surfaces,
the first side of the second laminated body has a stepped shape with stepped surfaces where the fifth electrode pads or the sixth electrode pads are located, and
in a plan view of the main surface, an end portion of the second laminated body on the first side is located closer to the first side than an end portion of the third laminated body on the first side.

5. The semiconductor device according to claim 3 further comprising:
a second resin layer that is in contact with a lower surface of the second plate-shaped portion in the second laminated body and is in contact with an upper surface of the first laminated body and an upper surface of the third laminated body.

6. The semiconductor device according to claim 3, further comprising:
a first semiconductor chip that is connected to the main surface of the wiring substrate between the first laminated body and the third laminated body.

7. The semiconductor device according to claim 6, further comprising:
a second resin layer that is in contact with a lower surface of the second plate-shaped portion in the second laminated body and is in contact with an upper surface of the first laminated body and an upper surface of the third laminated body, and
an upper surface of the first semiconductor chip is in contact with the second resin layer.

8. The semiconductor device according to claim 4, wherein the second plate-shaped portion further includes a third resin layer connected to the second side of the fifth memory chip and a first semiconductor layer connected to the first side of the first resin layer and the second side of the third resin layer.

9. The semiconductor device according to claim 4,
wherein the fifth memory chip in the second plate-shaped portion is connected to the first side of the first resin layer, and
the semiconductor device further includes
a first semiconductor layer provided above the first resin layer.

10. The semiconductor device according to claim 4,
wherein the fifth memory chip in the second plate-shaped portion is connected to the first side of the first resin layer, and
the semiconductor device further includes
a first semiconductor layer provided below the first resin layer.

11. The semiconductor device according to claim 1, further comprising:
a controller chip that is provided below the first laminated body and is connected to the main surface of the wiring substrate.

12. A semiconductor device comprising:
a wiring substrate that has a main surface intersecting an up-down direction; and
a fourth laminated body that includes L (L is an integer of equal to or greater than one) sixth plate-shaped portions and L seventh plate-shaped portions having a first width in a first width direction intersecting the up-down direction and an eighth plate-shaped portion having a second width that is wider than the first width in the first width direction, the L sixth plate-shaped portions being laminated in the up-down direction above the wiring substrate, the L seventh plate-shaped portions being laminated in the up-down direction on a first side of the L sixth plate-shaped portions in the first width direction, the eighth plate-shaped portion being provided over an upper surface of the uppermost sixth plate-shaped portion and an upper surface of the uppermost seventh plate-shaped portion,
wherein the sixth plate-shaped portions and the seventh plate-shaped portions include seventh memory chips and eighth memory chips, respectively,
the eighth plate-shaped portion includes a ninth memory chip, a fourth resin layer connected to the first side of the ninth memory chip, and a tenth memory chip provided on the first side of the fourth resin layer, and
the first side and a second side opposite to the first side of the fourth laminated body has a stepped shape.

13. The semiconductor device according to claim 12, wherein the eighth plate-shaped portion further includes a second semiconductor chip that has an upper surface in contact with a lower surface of the ninth memory chip and a lower surface of the tenth memory chip and controls the ninth memory chip and the tenth memory chip.

14. The semiconductor device according to claim 12, further comprising:
a fifth laminated body that includes K (K is an integer of equal to or greater than one) ninth plate-shaped portions and K tenth plate-shaped portions having the first width in the first width direction and an eleventh plate-shaped portion having the second width in the first width direction, the K ninth plate-shaped portions being laminated in the up-down direction above the L sixth plate-shaped portions, the K tenth plate-shaped portions being laminated in the up-down direction on the first side of the K ninth plate-shaped portions, and the eleventh plate-shaped portion being provided over an upper surface of the uppermost ninth plate-shaped portion and an upper surface of the uppermost tenth plate-shaped portion,
wherein the ninth plate-shaped portions and the tenth plate-shaped portions include eleventh memory chips and twelfth memory chips, respectively,
the eleventh plate-shaped portion includes a thirteenth memory chip, a fifth resin layer connected to the first side of the thirteenth memory chip, and a fourteenth memory chip provided on the first side of the fifth resin layer, and
the first side and the second side of the fifth laminated body have a stepped shape.

15. The semiconductor device according to claim 14, wherein in a plan view of the main surface, an end portion of the lowermost ninth plate-shaped portion on the second side is located closer to the second side than an end portion of the eighth plate-shaped portion on the second side, and an end portion of the lowermost tenth plate-shaped portion on the first side is located closer to the first side than an end portion of the eighth plate-shaped portion on the first side.

16. A semiconductor device comprising:
a wiring substrate that has a main surface intersecting an up-down direction;
a first laminated body that includes N (N is an integer of equal to or greater than two) first plate-shaped portions having a first width in a first width direction intersecting the up-down direction, the N first plate-shaped portions being laminated in the up-down direction above the wiring substrate;
a third laminated body that includes N fourth plate-shaped portions having the first width in the first width direction, the N fourth plate-shaped portions being laminated in the up-down direction on a first side of the first laminated body in the first width direction; and
a second laminated body that includes (i) a second plate-shaped portion having a second width that is wider than the first width in a second width direction intersecting the up-down direction and the first width direction and provided over an upper surface of the first laminated body and an upper surface of the third laminated body, (ii) M (M is an integer of equal to or greater than one) third plate-shaped portions provided above the second plate-shaped portion and having the first width in the second width direction, and (iii) M fifth plate-shaped portions having the first width in the second width direction, the second plate-shaped portion and the M third plate-shaped portions being laminated in the up-down direction, the M fifth plate-shaped portions being laminated in the up-down direction on a third side of the M third plate-shaped portions in the second width direction,
wherein the first plate-shaped portions include first memory chips provided with first electrode pads, which are electrically connected to the wiring substrate through a first bonding wire, on upper surfaces,
the fourth plate-shaped portions include fourth memory chips provided with fourth electrode pads, which are electrically connected to the wiring substrate through a third bonding wire, on upper surfaces,
the second plate-shaped portion includes a second memory chip provided with second electrode pads, which are electrically connected to the wiring substrate through a second bonding wire, on an upper surface, a first resin layer connected to the third side of the second memory chip in the second width direction, and a fifth memory chip provided with fifth electrode pads, which are electrically connected to the wiring substrate through a fourth bonding wire, on an upper surface and provided on the third side of the first resin layer,
the third plate-shaped portions include third memory chips provided with third electrode pads, which are electrically connected to the wiring substrate through the second bonding wire, on upper surfaces,
the fifth plate-shaped portions include sixth memory chips provided with sixth electrode pads, which are electrically connected to the wiring substrate through the fourth bonding wire, on upper surfaces,
a second side of the first laminated body opposite to the first side in the first width direction has a stepped shape with stepped surfaces where the first electrode pads are located,
the first side of the third laminated body in the first width direction has a stepped shape with stepped surfaces where the fourth electrode pads are located,
a fourth side of the second laminated body opposite to the third side in the second width direction has a stepped shape with stepped surfaces where the second electrode pads or the third electrode pads are located, and
the third side of the second laminated body in the second width direction has a stepped shape with stepped surfaces where the fifth electrode pads or the sixth electrode pads are located.

17. The semiconductor device according to claim 1,
wherein the plate-shaped portions including any memory chips from among the first memory chips to the third memory chips further include second semiconductor chips that have upper surfaces in contact with lower surfaces of the memory chips and control the memory chips, and
a width of the second semiconductor chips in the first width direction is wider than a width of the memory chips in the first width direction.

18. The semiconductor device according to claim 17,
wherein first pads are formed on upper surfaces of the second semiconductor chips,
second pads are formed on lower surfaces of the memory chips, and
the memory chips and the second semiconductor chips are affixed by the first pads and the second pads being joined to each other.

19. The semiconductor device according to claim 18, wherein the memory chips include vias that electrically connect the second pads and the electrode pads provided on upper surfaces of the memory chips and follow the up-down direction.
